(19) United States
(12) Patent Application Publication
(10) Pub. No.: US 2025/0294975 A1
(43) Pub. Date: Sep. 18, 2025

(54) LIGHT-EMITTING DIODE, DISPLAY DEVICE INCLUDING THE SAME, AND ELECTRONIC DEVICE INCLUDING THE SAME

(71) Applicant: Samsung Display Co., Ltd., Yongin-si (KR)

(72) Inventors: Donguk Kim, Yongin-si (KR); Hyunho Kim, Yongin-si (KR); Hoongi Lee, Yongin-si (KR)

(73) Assignee: Samsung Display Co., Ltd., Yongin-si (KR)

(21) Appl. No.: 19/030,636

(22) Filed: Jan. 17, 2025

(30) Foreign Application Priority Data
Mar. 14, 2024 (KR) 10-2024-0035981

(51) Int. Cl. H10K 59/124; H10K 59/122; H10K 59/80

(52) U.S. Cl. CPC H10K 59/124; H10K 59/122; H10K 59/877

(57) ABSTRACT

A display device includes a pixel circuit layer, a via insulating layer on the pixel circuit layer and including a groove, and a light-emitting diode including a first area overlapping the groove and a second area surrounding the first area in a plan view. The light-emitting diode includes a first electrode including a first portion disposed in the groove in the first area and a second portion extending from the first portion and disposed in the second area, a light scattering layer on the first portion of the first electrode and including a scattering body, a light-transmitting conductive layer on the light scattering layer, an emission layer on the light-transmitting conductive layer, and a second electrode on the emission layer. A distance between a substrate and the first portion of the first electrode is less than a distance between the substrate and the second portion of the first electrode.

### CROSS-REFERENCE TO RELATED APPLICATION(S)

This application claims priority to and benefits of Korean Patent Application No. 10-2024-0035981 under 35 U.S.C. § 119, filed on Mar. 14, 2024, in the Korean Intellectual Property Office (KIPO), the entire contents of which are incorporated herein by reference.

### BACKGROUND

### 1. Technical Field

Embodiments relate to a light-emitting diode, a display device including the light-emitting diode, and an electronic device including the light-emitting diode.

### 2. Description of the Related Art

Display devices visually display data. Display devices are used as displays of compact products such as mobile phones or as displays of large-sized products such as televisions.

A display device includes a plurality of pixels that receive electrical signals and emit light to display an image to the outside. Each of the pixels includes a light-emitting diode. For example, an organic light-emitting display device includes an organic light-emitting diode (OLED) as a light-emitting diode.

### SUMMARY

Embodiments include a display device with reduced luminance and/or color deviation caused by a viewing angle and excellent light efficiency. However, this objective is only an example, and the scope of the disclosure is not limited thereby.

Additional aspects will be set forth in part in the description which follows and, in part, will be apparent from the description, or may be learned by practice of the presented embodiments of the disclosure.

According to an embodiment, a display device may include a pixel circuit layer disposed on a substrate and including a thin-film transistor, a via insulating layer disposed on the pixel circuit layer and including a groove, and a light-emitting diode disposed on the via insulating layer and including a first area overlapping the groove and a second area surrounding the first area in a plan view. The light-emitting diode may include a first electrode including a first portion disposed in the groove in the first area and a second portion extending from the first portion and disposed in the second area, a light scattering layer disposed on the first portion of the first electrode and including a scattering body, a light-transmitting conductive layer disposed on the light scattering layer, an emission layer disposed on the light-transmitting conductive layer, and a second electrode on the emission layer. A distance between the substrate and the first portion of the first electrode may be less than a distance between the substrate and the second portion of the first electrode.

An upper surface of the via insulating layer may include a first surface, a second surface at a higher level than the first surface, and a third surface connecting the first surface to the second surface, and the first surface of the via insulating layer and the third surface of the via insulating layer may define the groove.

The first portion of the first electrode may be disposed on the first surface of the via insulating layer and the third surface of the via insulating layer, and the second portion of the first electrode may be disposed on the second surface of the via insulating layer.

An angle between the first surface of the via insulating layer and the third surface of the via insulating layer may be in a range of about 20° to about 40°.

The light scattering layer may be disposed in the groove of the via insulating layer.

The light-transmitting conductive layer may contact the light scattering layer in the first area and contact the first electrode in the second area.

The light-transmitting conductive layer may include a first inorganic layer and a second inorganic layer on the first inorganic layer.

The display device may further include a pixel-defining layer on the light-transmitting conductive layer, the pixel-defining layer including a pixel opening that exposes a part of the light-transmitting conductive layer.

In a plan view, an area of the first area may be about 20% to about 80% of an area of a light-emitting area of the light-emitting diode defined by the pixel-defining layer.

In a plan view, the area of the first area may be less than an area of the second area.

In a plan view, the area of the first area may be greater than an area of the second area.

The display device may further include an insulating pattern overlapping the pixel-defining layer in a plan view and disposed between the via insulating layer and the first electrode. The first electrode may further include a third portion extending from the second portion and disposed on a side surface of the insulating pattern.

A thickness of the light scattering layer may be in a range of about 1.5 μm to about 4 μm.

The display device may further include an encapsulation layer disposed on the light-emitting diode and encapsulating the light-emitting diode, and a color filter layer disposed on the encapsulation layer.

According to an embodiment, a display device may include a pixel circuit layer disposed on a substrate and including a thin-film transistor, a via insulating layer disposed on the pixel circuit layer and including a groove, a first electrode including a first portion disposed in the groove of the via insulating layer and a second portion extending from the first portion and disposed outside the groove, a light scattering layer disposed on the first portion of the first electrode and including a scattering body, an emission layer disposed on the light scattering layer, a second electrode on the emission layer, and a light-transmitting conductive portion including a portion disposed between the light scattering layer and the emission layer and another portion disposed between the second portion of the first electrode and the emission layer.

An upper surface of the via insulating layer may include a first surface, a second surface at a higher level than the first surface, and a third surface connecting the first surface to the second surface, and the first surface of the via insulating layer and the third surface of the via insulating layer may define the groove.

The first portion of the first electrode may be disposed on the first surface of the via insulating layer and the third surface of the via insulating layer, and the second portion of the first electrode may be disposed on the second surface of the via insulating layer.

An angle between the first surface of the via insulating layer and the third surface of the via insulating layer may be in a range of about 20° to about 40°.

The display device may further include a pixel-defining layer disposed on the first electrode and including a pixel opening that exposes part of the first electrode.

The display device may further include an insulating pattern overlapping the pixel-defining layer in a plan view and disposed between the via insulating layer and the first electrode. The first electrode may further include a third portion extending from the second portion and disposed on a side surface of the insulating pattern.

A thickness of the light scattering layer may be in a range of about 1.5 μm to about 4 μm.

The display device may further include an encapsulation layer disposed on the second electrode, and a color filter layer disposed on the encapsulation layer.

According to an embodiment, a light-emitting diode may include a first electrode including a first portion and a second portion, the first portion comprising a flat portion and an inclination portion, and the second portion surrounding the first portion in a plan view and connected to the flat portion of the first portion by the inclination portion of the first portion, a light scattering layer disposed on the first portion of the first electrode and including a scattering body, a light-transmitting conductive layer disposed on the light scattering layer, an emission layer disposed on the light-transmitting conductive layer, and a second electrode disposed on the emission layer.

An upper surface of the second portion may be at a higher level than an upper surface of the flat portion of the first portion, and the inclination portion of the first portion may be disposed between the flat portion and the second portion and inclined from the flat portion of the first portion.

The light-transmitting conductive layer may be in contact with the second portion of the first electrode, and the light scattering layer may be disposed between the first portion of the first electrode and the light-transmitting conductive layer.

A thickness of the light scattering layer may be in a range of about 1.5 μm to about 4 μm.

According to one or more embodiments, an electronic device includes a display device, wherein the display device may include a pixel circuit layer disposed on a substrate and including a thin-film transistor, a via insulating layer disposed on the pixel circuit layer and including a groove, a first electrode including a first portion disposed in the groove of the via insulating layer and a second portion extending from the first portion and disposed outside the groove, a light scattering layer disposed on the first portion of the first electrode and including a scattering body, an emission layer disposed on the light scattering layer, a second electrode on the emission layer, and a light-transmitting conductive portion including a portion disposed between the light scattering layer and the emission layer and another portion disposed between the second portion of the first electrode and the emission layer.

In an embodiment, the electronic device may further include a display module, a processor, a power module, and a memory, wherein the display device may include one of the display module, the processor, the power module, or the memory.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are perspective views schematically illustrating a display device according to an embodiment;

FIG. 2 shows a display element and a pixel circuit connected to the display element in one pixel of a display device, according to an embodiment;

FIG. 3 is a schematic cross-sectional view of the display device according to an embodiment, taken along line A-A′ in FIG. 1A;

FIG. 4 is a plan view illustrating part of a pixel arrangement in a pixel area of a display device according to an embodiment;

FIG. 5 is a schematic cross-sectional view illustrating part of a display area of a display device according to an embodiment;

FIG. 6 is an enlarged view of region B of FIG. 5 according to an embodiment;

FIG. 7 is a plan view illustrating part of a pixel arrangement in a pixel area of a display device according to another embodiment;

FIG. 8 is an enlarged view of region B of FIG. 5 according to another embodiment;

FIG. 9 is an enlarged view of region B of FIG. 5 according to another embodiment;

FIG. 10 is a graph showing luminance ratios depending on viewing angles in a comparative example and examples wherein a pixel emitting red light is included;

FIG. 11 is a graph showing luminance ratios depending on viewing angles in a comparative example and examples wherein a pixel emitting green light is included;

FIG. 12 is a graph showing luminance ratios depending on viewing angles in a comparative example and examples wherein a pixel emitting blue light is included; and

FIGS. 13 to 19 are schematic cross-sectional views illustrating a method of manufacturing a display device, according to an embodiment.

FIG. 20 is a block diagram of an electronic device according to an embodiment.

FIG. 21 is a schematic diagrams of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Hereinafter, embodiments will be described with reference to the accompanying drawings, wherein like reference numerals refer to like elements throughout and a repeated description thereof is omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the following embodiments, when a part of a film, area, element, or the like is disposed over or on another part, it refers not only to a case where the part is directly on top of the other part, but also a case where another film, area, element, or the like is located therebetween.

In the drawings, for convenience of description, the sizes of elements may be exaggerated or reduced. For example, the size and thickness of each element shown in the drawings are shown arbitrarily for convenience of description, and thus, the disclosure is not necessarily limited to shown.

When an embodiment can be implemented differently, a specific process sequence may be performed differently from the described sequence. For example, two processes described in succession may be performed substantially at the same time, or may be performed in an order opposite to the described sequence.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the following embodiments, when films, areas, elements, or the like are described to be connected, it includes a case where the films, the areas, the elements, or the like are directly connected, or/and a case where the films, the areas, the elements, or the like are indirectly connected with other films, areas, or elements therebetween. For example, herein, when it is described that films, areas, elements, or the like are electrically connected, it indicates a case where the films, areas, elements, or the like are directly electrically connected, or/and a case where the films, areas, the elements, or the like are indirectly electrically connected with other films, areas, or elements therebetween.

An x-axis, a y-axis, and a z-axis are not limited to the three axes in the Cartesian coordinate system, but can be interpreted in a broad sense including the same. For example, the x-axis, the y-axis, and the z-axis may be orthogonal to each other, but may also refer to directions that are not orthogonal to each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

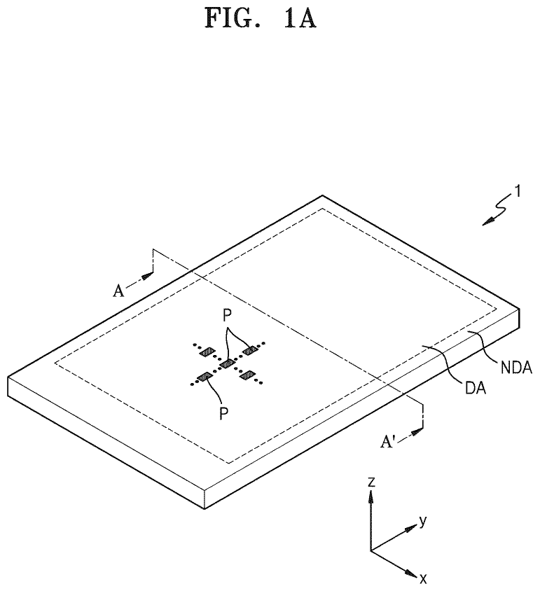

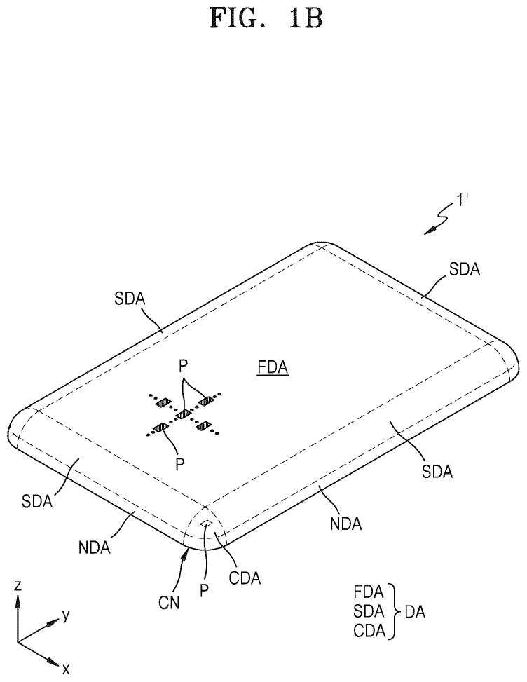

FIGS. 1A and 1B are perspective views schematically illustrating display devices 1 and 1′, respectively, according to an embodiment. FIG. 1A schematically illustrates the display device 1 in a flat state, and FIG. 1B illustrates the display device 1′ including a three-dimensional display surface or a curved display surface.

In an embodiment, each of the display devices 1 and 1′ may be a device configured to display moving images or still images and may be used as display screens of various products such as televisions, laptops, monitors, billboards, or Internet of Things (IoT) as well as portable devices such as a mobile phone, a smartphone, a tablet personal computer (PC), a mobile communication terminal, an electronic notebook, an e-book reader, a portable multimedia player (PMP), a navigation system, an ultra-mobile PC (UMPC).

In an embodiment, the display devices 1 and 1′ may be used for wearable devices such as a smart watch, a watch phone, a glasses-type display, and a head-mounted display (HMD). In an embodiment, the display devices 1 and 1′ may be used as displays for an instrument panel of a vehicle, a center information display (CID) disposed on a center fascia or dashboard of a vehicle, a room mirror display replacing side-view mirrors of a vehicle, or as displays disposed on the rear surfaces of the front seats as an entertainment device for the backseat of a vehicle.

Referring to FIGS. 1A and 1B, the display devices 1 and 1′ may each include a display area DA and a non-display area NDA adjacent to the display area DA. Multiple pixels P including display elements may be disposed in the display area DA, and the display devices 1 and 1′ may each provide images by using light emitted from the pixels P disposed in the display area DA. The non-display area NDA may be an area in which display elements are not disposed, and the display area DA may be entirely surrounded by the non-display area NDA in a plan view.

The display devices 1 and 1′ may be each provided in various shapes in a plan view, for example, in a rectangular plate shape having two pairs of sides parallel to each other. In FIGS. 1A and 1B, for convenience of description, the display devices 1 and 1′ may each have a rectangular shape having one pair of long sides and one pair of short sides. However, the shapes of the display devices 1 and 1′ are not limited thereto and may vary. For example, the display devices 1 and 1′ may be provided in various shapes such as a closed polygon including straight lines, a circle or an ellipse including a curved side, or a semicircle or a semi-ellipse including straight and curved sides.

The display area DA may be a portion in which an image is displayed, and the pixels P may be disposed in the display area DA. Each of the pixels P may include a display element such as an organic light-emitting diode. Each of the pixels P may emit, for example, red, green, blue, or white light.

The display area DA may provide an image through light emitted from the pixels P. The pixel P as used herein may be defined as a light-emitting area in which one of red, green, blue, and white light is emitted, as described above.

The non-display area NDA may be an area in which a pixel P is not disposed, and may not provide images. In the non-display area NDA, a printed circuit board including a power supply line and a driving circuit part for driving the pixels P or a terminal part to which a driver integrated circuit (IC) is connected may be disposed.

The display devices 1 and 1′ according to an embodiment may be an organic light-emitting display, an inorganic light-emitting display (or inorganic electroluminescent (EL) display), or a quantum dot light-emitting display. For example, emission layers included in the light-emitting diodes provided in the display devices 1 and 1′ may include an organic material or an inorganic material. In an embodiment, quantum dots may be positioned on a path of light emitted from the emission layer.

Referring to FIG. 1B, the display device 1′ may include a three-dimensional display surface or a curved display surface. In another embodiment, in case that the display device 1′ includes a curved display surface, the display device 1′ may be implemented in various forms such as flexible, foldable, or rollable display devices.

As shown in FIG. 1B, in case that the display device 1′ has straight sides, at least some of edges of each shape may be curved. For example, in case that the display device 1′ has a rectangular shape, a portion at which adjacent straight sides meet each other may be replaced with a curved line having a curvature. In other words, a vertex portion of the rectangular shape may have opposite adjacent ends respectively connected to two adjacent straight lines, and may include curved sides having a curvature. The curvature may be set depending on a location. For example, the curvature may vary depending on a position at which a curved line starts and a length of the curved line.

The display area DA of the display device 1′ of FIG. 1B may include a front display area FDA, a side display area SDA, and a corner display area CDA.

In an embodiment, the pixels P each having a display element may be disposed in the front display area FDA, the side display area SDA, and the corner display area CDA. In an embodiment, each of the pixels P may provide an independent image. In another embodiment, each of the pixels P in the front display area FDA, the side display area SDA, and the corner display area CDA may provide a portion of an image.

For example, the front display area FDA may be a non-bending area, and the side display area SDA and the corner display area CDA may be a bending area that is bendable at a curvature.

The side display area SDA may be disposed at each of the four edges of the front display area FDA. The side display area SDA may be disposed on a left side (e.g., a-x direction) and a right side (e.g., an x direction) with the front display area FDA between the left side and the right side, and may be bent with respect to a bending axis in a long-axis direction (e.g., a y direction). The side display area SDA may be disposed on an upper side (e.g., the y direction) and a lower side (e.g., a −y direction) with the front display area FDA between the upper side and the lower side, and may be bent with respect to a bending axis in a short-axis direction (e.g., the x direction). Accordingly, the display device 1′ according to the embodiment may have a four-sided bending structure.

The corner display area CDA may be disposed and bent at a corner CN of the display device 1′. In other words, the corner display area CDA may be disposed to correspond to the corner CN. The corner CN may be a portion at which a long side in the long-axis direction (e.g., the y direction) and a short side in the short-axis direction (e.g., the x direction) meet each other. The corner display area CDA may be disposed between neighboring side display areas SDA. The side display area SDA and the corner display area CDA may at least partially surround the front display area FDA and may be bent.

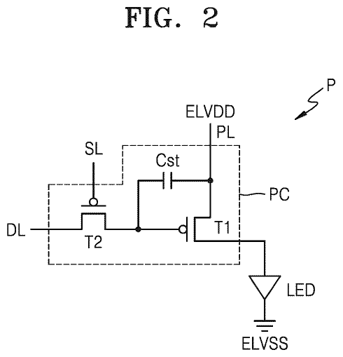

FIG. 2 illustrates a display element and a pixel circuit PC connected to the display element provided in one pixel P of a display device, according to an embodiment.

Referring to FIG. 2, a light-emitting diode LED, which is a display element, may be electrically connected to the pixel circuit PC. The pixel circuit PC may include a first thin-film transistor T1, a second thin-film transistor T2, and a storage capacitor Cst. For example, the light-emitting diode LED may emit one of red, green, and blue light or one of red, green, blue, and white light.

The second thin-film transistor T2, which is a switching thin-film transistor, may be connected to a scan line SL and a data line DL and may transfer a data voltage received via the data line DL to the first thin-film transistor T1 in response to a switching voltage received via the scan line SL. The storage capacitor Cst may be connected to the second thin-film transistor T2 and a driving voltage line PL and may store a voltage corresponding to a voltage difference between a voltage received from the second thin- film transistor T2 and a first power voltage ELVDD supplied from the driving voltage line PL.

The first thin-film transistor T1, which is a driving transistor, may be connected to the driving voltage line PL and the storage capacitor Cst and may control a driving current flowing to the light-emitting diode LED from the driving voltage line PL to correspond to a voltage value stored in the storage capacitor Cst. The light-emitting device LED may emit light having a luminance according to the driving current. A first electrode (e.g., an anode) of the light-emitting diode LED may be connected to the pixel circuit PC, and a second electrode (e.g., a cathode) of the light-emitting diode LED may receive a second power voltage ELVSS.

FIG. 2 illustrates that the pixel circuit PC includes two thin-film transistors and one storage capacitor. However, the disclosure is not limited thereto, and the number of thin-film transistors and the number of storage capacitors may be variously modified depending on a design of the pixel circuit PC.

In an embodiment, each of the first thin-film transistor T1 and the second thin-film transistor T2 may be provided as a p-channel metal-oxide-semiconductor field-effect transistor (MOSFET; PMOS) or as an n-channel MOSFET (NMOS). In an embodiment, some of the transistors included in the pixel circuit PC may be provided as PMOSs, and the others may be provided as NMOSs.

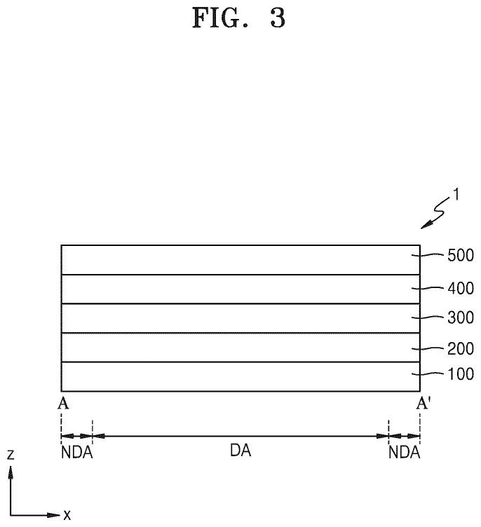

FIG. 3 is a schematic cross-sectional view of the display device 1 according to an embodiment, taken along line A-A′ in FIG. 1A.

Referring to FIG. 3, the display device 1 according to an embodiment may include a substrate 100, a display layer 200, an encapsulation layer 300, a touch sensing layer 400, and an anti-reflection layer 500.

The substrate 100 may include glass or a polymer resin. For example, the polymer resin may include polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including polymer resin may have flexible, rollable, or bendable properties. The substrate 100 may have a multi-layer structure including a layer including polymer resin and an inorganic layer.

The display layer 200 may be disposed on the substrate 100. The display layer 200 may include a light-emitting diode, a thin-film transistor electrically connected to the light-emitting diode, and insulating layers positioned between the light-emitting diode and the thin-film transistor.

The encapsulation layer 300 may be disposed on the display layer 200. For example, the display layer 200 may be sealed by the encapsulation layer 300. In an embodiment, the encapsulation layer 300 may include at least one inorganic film layer and at least one organic film layer.

The touch sensing layer 400 may be disposed on the encapsulation layer 300. The touch sensing layer 400 may detect an external input, for example, a touch of an object such as a finger or a stylus pen, so that the display device 1 may obtain coordinate information corresponding to a touch position. The touch sensing layer 400 may include a touch electrode and trace lines connected to the touch electrode. The touch sensing layer 400 may detect an external input by using a mutual capacitance method or a self-capacitance method.

In an embodiment, the touch sensing layer 400 may be formed on (e.g., directly formed on) the encapsulation layer 300. In another embodiment, the touch sensing layer 400 may be separately formed and be bonded to the encapsulation layer 300 through an adhesive layer such as an optically clear adhesive (OCA).

The anti-reflection layer 500 may be disposed on the touch sensing layer 400. The anti-reflection layer 500 may reduce reflectivity of light (external light) incident toward the display device 1. FIG. 3 illustrates that the anti-reflection layer 500 is disposed on the touch sensing layer 400. However, the disclosure is not limited thereto. In another embodiment, the anti-reflection layer 500 may be disposed on the encapsulation layer 300, and the touch sensing layer 400 may be disposed on the anti-reflection layer 500. In other words, in another embodiment, the anti-reflection layer 500 may be disposed between the encapsulation layer 300 and the touch sensing layer 400.

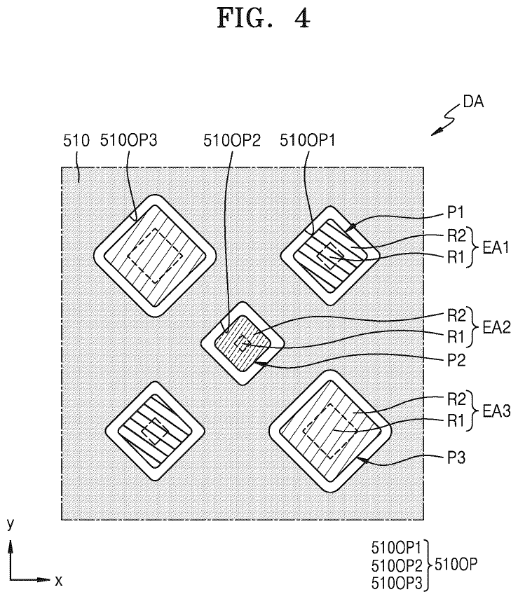

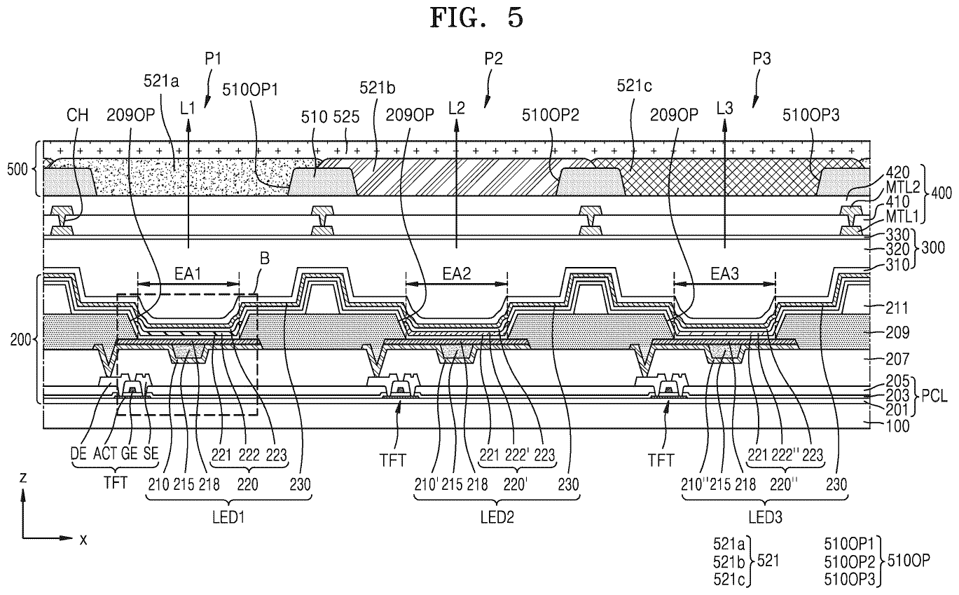

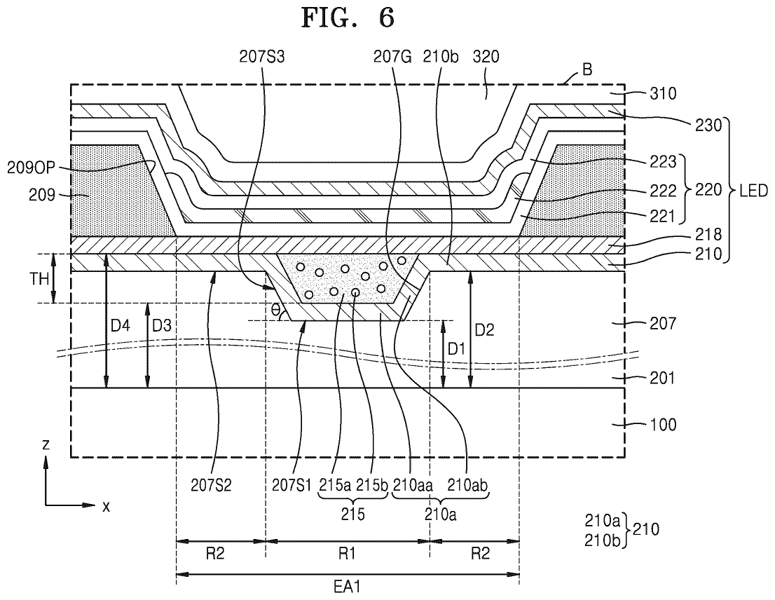

FIG. 4 is a schematic plan view illustrating a portion of a pixel arrangement in the display area DA of the display device 1 according to an embodiment. FIG. 5 is a schematic cross-sectional view illustrating a portion of the display area DA of the display device 1 according to an embodiment. FIG. 6 is a schematic enlarged view of region B of FIG. 5 according to an embodiment.

Referring to FIG. 4, the display device 1 may include multiple pixels, which may include a first pixel P1, a second pixel P2, and a third pixel P3 emitting light of different colors. For example, the first pixel P1 may emit red light L1, the second pixel P2 may emit green light L2, and the third pixel P3 may emit blue light L3. However, the disclosure is not limited thereto, and various modifications may be made. For example, the first pixel P1 may emit blue light, the second pixel P2 may emit green light, and the third pixel P3 may emit red light.

The first pixel P1, the second pixel P2, and the third pixel P3 may have a rectangular shape among polygonal shapes in a plan view. Herein, polygons or rectangles also include shapes with round corners. In another embodiment, the first pixel P1, the second pixel P2, and the third pixel P3 may have a circular or elliptical shape in a plan view.

The first pixel P1, the second pixel P2, and the third pixel P3 may have different sizes in a plan view. For example, an area of the second pixel P2 may be smaller than an area of the first pixel P1 and the third pixel P3, and the area of the third pixel P3 may be greater than the area of the first pixel P1. In another embodiment, the first pixel P1, the second pixel P2, and the third pixel P3 may have substantially the same size, and various modifications may be made.

Herein, the sizes of the first pixel P1, the second pixel P2, and the third pixel P3 may be sizes of first to third light-emitting areas EA1, EA2, and EA3 of display elements implementing the respective pixels, and the first to third light-emitting areas EA1, EA2, and EA3 may be defined by a pixel opening 209OP of a pixel-defining layer 209 (see FIG. 5).

The first to third light-emitting areas EA1, EA2, and EA3 of the display elements may include a first area R1 overlapping a groove 207G (FIG. 6) of a via insulating layer 207 described below, and a second area R2 surrounding the first area R1 in a plan view. In other words, each light-emitting diode, which is a display element, may include the first area R1 and the second area R2. The first area R1 may be disposed at the center of the light-emitting diode, and the second area R2 may be disposed outside the first area R1. In an embodiment, in a plan view, an area of the first area R1 may be less than an area of the second area R2. However, the disclosure is not limited thereto, and in another embodiment, the area of the first area R1 may be greater than the area of the second area R2. In another embodiment, the area of the first area R1 and the area of the second area R2 may be substantially the same. For example, the area of the first area R1 may be about 20% to about 80% of the area of each of the first to third light-emitting areas EA1, EA2, and EA3. In case that the area of the first area R1 is less than about 20% of the area of each of the first to third light-emitting areas EA1, EA2, and EA3, luminance deviation and/or color deviation depending on the viewing angle of the display device 1 may increase significantly. In case that the area of the first area R1 is greater than about 80% of the area of each of the first to third light-emitting areas EA1, EA2, and EA3, front light efficiency of the display device 1 may decrease significantly. The area of each of the first area R1 and the second area R2 may be an area viewed in a direction facing the upper surface of the substrate 100 (e.g., a −z direction).

A light-shielding layer 510 disposed over the display layer 200 may have first to third openings 510OP1, 510OP2, and 510OP3 respectively corresponding to the first to third pixels P1, P2, and P3. The first to third openings 510OP1, 510OP2, and 510OP3 may be areas obtained by removing part of the light-shielding layer 510, and light emitted by the display elements may be emitted to the outside through the first to third openings 510OP1, 510OP2, and 510OP3 defined in the light-shielding layer 510. A body portion of the light-shielding layer 510 may have a material that absorbs external light, and thus, the visibility of the display device 1 may be improved.

In a plan view, the first to third openings 510OP1, 510OP2, and 510OP3 defined in the light-shielding layer 510 may surround the pixels P1, P2, and P3, respectively. The first to third openings 510OP1, 510OP2, and 510OP3 defined in the light-shielding layer 510 may have a rectangular shape with round edges, a circular shape, or an elliptical shape. The areas of the first to third openings 510OP1, 510OP2, and 5100P3 respectively corresponding to the pixels P1, P2, and P3 may be greater than the areas of the pixels P1, P2, and P3, respectively. However, the disclosure is not limited thereto. The areas of the first to third openings 510OP1, 510OP2, and 510OP3 defined in the light-shielding layer 510 and the areas of the pixels P1, P2, and P3 may be substantially the same, respectively.

As shown in FIG. 4, the first pixel P1, the second pixel P2, and the third pixel P3 may be disposed in a pixel arrangement of a PenTile™ structure. However, the disclosure is not limited thereto. For example, the first pixel P1, the second pixel P2, and the third pixel P3 may be disposed in various pixel array structures such as a stripe structure, a mosaic structure, and a delta structure.

Referring to FIGS. 5 and 6, the display device 1 may include the substrate 100, the display layer 200, the encapsulation layer 300, the touch sensing layer 400, and the anti-reflection layer 500.

The display layer 200 may include a pixel circuit layer PCL including a thin-film transistor TFT and insulating layers, the via insulating layer 207 disposed on the pixel circuit layer PCL, and first to third light-emitting diodes LED1, LED2, and LED3. In an embodiment, the display layer 200 may further include the pixel-defining layer 209 and/or a spacer 211.

The pixel circuit layer PCL may be disposed on the substrate 100. The pixel circuit layer PCL may include a buffer layer 201, a gate insulating layer 203, an interlayer insulating layer 205, which are insulating layers, and the thin-film transistor TFT.

The buffer layer 201 may be disposed on the substrate 100 to reduce, or block permeation of foreign substances, moisture, or external air through the lower portion of the substrate 100 and may provide a flat surface on the substrate 100. The buffer layer 201 may include an inorganic material such as an oxide or nitride, an organic material, or an organic and inorganic compound, and may have a single-layered or multi-layered structure of an inorganic material and an organic material. A barrier layer (not shown) for blocking permeation of external air may be further included between the substrate 100 and the buffer layer 201. The buffer layer 201 may include silicon oxide (SiO₂) or silicon nitride (SiNₓ).

The thin-film transistors TFT may be disposed on the buffer layer 201. Each of the thin-film transistors TFT may include a semiconductor layer ACT, a gate electrode GE, a source electrode SE, and a drain electrode DE. The thin-film transistors TFT may be electrically connected to the first to third light-emitting diodes LED1, LED2, and LED3, respectively, to drive the first to third light-emitting diodes LED1, LED2, and LED3.

The semiconductor layer ACT may be disposed on the buffer layer 201 and may include polysilicon. In another embodiment, the semiconductor layer ACT may include amorphous silicon. In another embodiment, the semiconductor layer ACT may include an oxide of at least one of indium (In), gallium (Ga), tin (Sn), zirconium (Zn), vanadium (V), hafnium (Hf), cadmium (Cd), germanium (Ge), chrome (Cr), titanium (Ti), and zinc (Zn). The semiconductor layer ACT may include a channel region, and a source region and a drain region that are doped with impurities.

The gate electrode GE, the source electrode SE, and the drain electrode DE may include a conductive material. The gate electrode GE may include at least one of molybdenum, aluminum, copper, and Ti. For example, the gate electrode GE may be a single molybdenum layer or a three-layer structure including a molybdenum layer, an aluminum layer, and a molybdenum layer. The source electrode SE and the drain electrode DE may each include at least one of copper, titanium Ti, and aluminum. For example, the source electrode SE and the drain electrode DE may each have a three-layer structure including a Ti layer, an aluminum layer, and a Ti layer.

In order to ensure insulation between the semiconductor layer ACT and the gate electrode GE, the gate insulating layer 203 including an inorganic material, such as silicon oxide, silicon nitride, and/or silicon oxynitride, may be positioned between the semiconductor layer ACT and the gate electrode GE. In an embodiment, the interlayer insulating layer 205 including an inorganic material, such as silicon oxide, silicon nitride, and/or silicon oxynitride, may be disposed over the gate electrode GE, and the source electrode SE and the drain electrode DE may be disposed on the interlayer insulating layer 205 described above. An insulating film including an inorganic material as described above may be formed through chemical vapor deposition (CVD) or atomic layer deposition (ALD).

The via insulating layer 207 may be disposed on the thin-film transistor TFT. The via insulating layer 207 may be disposed on the interlayer insulating layer 205. The via insulating layer 207 may substantially planarize an upper portion of the thin- film transistor TFT.

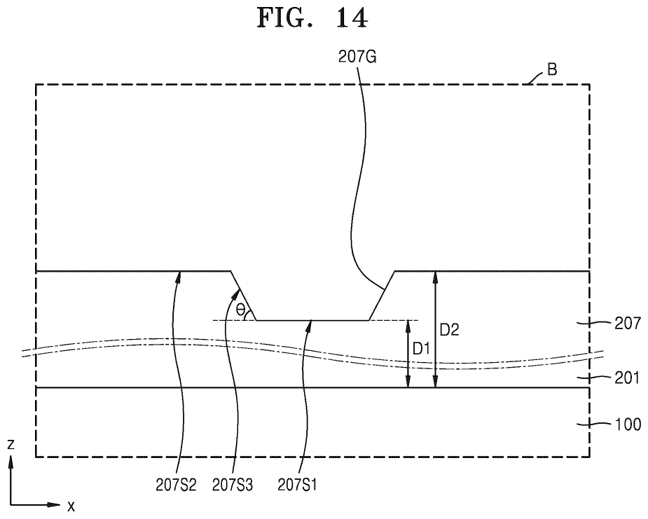

The via insulating layer 207 may have (or define) the groove 207G. The via insulating layer 207 may have an area having a concave shape toward the substrate 100. As described with reference to FIG. 14, the groove 207G of the via insulating layer 207 may be an area formed by removing a portion of the via insulating layer 207.

An upper surface of the via insulating layer 207 may include a first surface 207S1 positioned at a relatively lower level, a second surface 207S2 positioned at a higher level than the first surface 207S1, and a third surface 207S3 connecting the first surface 207S1 to the second surface 207S2. The third surface 207S3 of the via insulating layer 207 may be inclined from the first surface 207S1 and may be referred to as an inclined surface. The groove 207G of the via insulating layer 207 may be defined by the first surface 207S1 and the third surface 207S3 of the via insulating layer 207.

The term “level” as used herein may be defined as a vertical level representing a distance between an upper surface of the substrate 100 and a surface of an element, in a direction perpendicular to the substrate 100, for example, the z direction. In other words, in case that the level of “X” is lower than the level of “Y”, it may mean that a vertical distance between the upper surface of the substrate 100 and “X” is less than a vertical distance between the upper surface of the substrate 100 and “Y”. In other words, in case that the level of “X” is higher than the level of “Y”, it may mean that the vertical distance between the upper surface of the substrate 100 and “X” is greater than the vertical distance between the upper surface of the substrate 100 and “Y”. In case that the level of “X” is substantially the same as the level of “Y”, it may mean that the vertical level between the upper surface of the substrate 100 and “X” is substantially the same as the vertical distance between the upper surface of the substrate 100 and “Y”. For example, a distance D2 between the upper surface of the substrate 100 and the second surface 207S2 of the via insulating layer 207 may be greater than a distance D1 between the upper surface of the substrate 100 and the first surface 207S1 of the via insulating layer 207.

In an embodiment, an inclination angle of surfaces forming the groove 207G of the via insulating layer 207 may be in a range of about 20° to about 40°. In an embodiment, an angle θ between the first surface 207S1 and the third surface 207S3 of the via insulating layer 207 may be in a range of about 20° to about 40°. In an embodiment, the angle θ between the first surface 207S1 and the third surface 207S3 of the via insulating layer 207 may be in a range of about 20° to about 25°. In case that the angle θ between the first surface 207S1 and the third surface 207S3 of the via insulating layer 207 satisfies the range described above, a first electrode 210 formed on the via insulating layer 207 may have an inclination portion 210ab having the same or similar angle, and thus, luminance deviation and/or color deviation depending on the viewing angle may be improved. In case that the angle θ between the first surface 207S1 and the third surface 207S3 of the via insulating layer 207 is less than about 20°, the luminance deviation and/or color deviation depending on the viewing angle may increase. In case that the angle θ between the first surface 207S1 and the third surface 207S3 of the via insulating layer 207 exceeds about 40°, the front light efficiency of the display device 1 may decrease.

In an embodiment, the via insulating layer 207 may include an organic material such as general-purpose polymers, such as photosensitive polyimide (PSPI), polyimide, polystyrene (PS), polycarbonate (PC), benzocyclobutene (BCB), hexamethyldisiloxane (HMDSO), and poly(methyl methacrylate) (PMMA), a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer. FIG. 5 illustrates that the via insulating layer 207 includes a single layer. However, the disclosure is not limited thereto, and the via insulating layer 207 may include multiple layers.

The first to third light-emitting diodes LED1, LED2, and LED3 may be disposed on the via insulating layer 207. Each of the first to third light-emitting diodes LED1, LED2, and LED3 may include a first electrode, an intermediate layer on the first electrode, and a second electrode on the intermediate layer. For example, the first electrode may be an anode electrode, and the second electrode may be a cathode electrode, but the disclosure is not limited thereto. In another embodiment, the first electrode may be a cathode electrode, and the second electrode may be an anode electrode. In an embodiment, each of the first to third light-emitting diodes LED1, LED2, and LED3 may further include a light scattering layer 215 and a light-transmitting conductive layer 218.

The first light-emitting diode LED1 may include a first-1 electrode 210, a first intermediate layer 220, and a second electrode 230, and the first intermediate layer 220 may include a first common layer 221, a first emission layer 222, and a second common layer 223. The second light-emitting diode LED2 may include a first-2 electrode 210′, a second intermediate layer 220′, and the second electrode 230, and the second intermediate layer 220′ may include the first common layer 221, a second emission layer 222′, and the second common layer 223. The third light-emitting diode LED3 may include a first-3 electrode 210″, a third intermediate layer 220″, and the second electrode 230, and the third intermediate layer 220″ may include the first common layer 221, a third emission layer 222″, and the second common layer 223.

Hereinbelow, the description is based on the first light-emitting diode LED1 included in the first pixel P1, and because the second light-emitting diode LED2 included in the second pixel P2 and the third light-emitting diode LED3 included in the third pixel P3 and the first light-emitting diode LED1 have substantially a same stack structure, redundant descriptions thereof are omitted.

The first light-emitting diode LED1 (hereinbelow “the light-emitting diode LED”) may include the first-1 electrode 210 (hereinbelow “the first electrode 210”), the first intermediate layer 220 (hereinbelow “the intermediate layer 220”), and the second electrode 230.

The first electrode 210 may be disposed on the via insulating layer 207. The first electrode 210 may be disposed in each pixel. The first electrodes 210 respectively corresponding to neighboring pixels may be disposed to be spaced apart from each other.

The first electrode 210 may include a first portion 210a overlapping the groove 207G of the via insulating layer 207 in the first area R1 in a plan view, and a second portion 210b disposed outside of the groove 207G of the via insulating layer 207, in the second area R2. The first portion 210a of the first electrode 210 may be disposed at the center of each light-emitting diode LED and may be referred to as a central portion, and the second portion 210b of the first electrode 210 may be referred to as a peripheral portion.

The first portion 210a of the first electrode 210 may be disposed in the groove 207G of the via insulating layer 207. The second portion 210b of the first electrode 210 may extend from the first portion 210a and may be disposed outside the groove 207G of the via insulating layer 207. The first portion 210a of the first electrode 210 may be disposed at the center of the light-emitting diode LED, and the second portion 210b of the first electrode 210 may surround the first portion 210a in a plan view.

The first portion 210a of the first electrode 210 may be disposed on the first surface 207S1 and the third surface 207S3 of the via insulating layer 207. The second portion 210b of the first electrode 210 may be disposed on the second surface 207S2 of the via insulating layer 207.

The first portion 210a of the first electrode 210 may include a first-1 portion 210aa disposed on the first surface 207S1 and a first-2 portion 210ab disposed on the third surface 207S3. The first-1 portion 210aa of the first electrode 210 may be a flat portion having a substantially flat upper surface, and the first-2 portion 210ab may be an inclination portion inclined from the first-1 portion 210aa. Because the first electrode 210 includes the first-2 portion 210ab that is an inclination portion, luminance deviation and/or color deviation depending on the viewing angle may be improved.

An inclination angle between the first-1 portion 210aa and the first-2 portion 210ab of the first electrode 210 may be in a range of about 20° to about 40°. In an embodiment, the inclination angle between the first-1 portion 210aa and the first-2 portion 210ab of the first electrode 210 may be in a range of about 20° to about 25°.

The first electrode 210 may have a step structure. In an embodiment, an upper surface of the second portion 210b of the first electrode 210 may be disposed at a higher level than an upper surface of the first-1 portion 210aa of the first electrode 210. For example, the second portion 210b of the first electrode 210 may be connected to the first-1 portion 210aa of the first electrode 210 by the first-2 portion 210ab that is the inclination portion of the first electrode 210. In other words, the first-2 portion 210ab of the first electrode 210 may be disposed between the first-1 portion 210aa and the second portion 210b of the first electrode 210 and may connect the first-1 portion 210aa to the second portion 210b of the first electrode 210.

For example, a distance between the substrate 100 and the first portion 210a of the first electrode 210 may be less than a distance between the substrate 100 and the second portion 210b of the first electrode 210. For example, a distance between the upper surface of the substrate 100 and a lowermost surface of the first portion 210a of the first electrode 210 may be less than a distance between the substrate 100 and a lowermost surface of the second portion 210b of the first electrode 210. Herein, a distance between A and B may be defined as a shortest vertical distance between A and B.

For example, the upper surface of the second portion 210b of the first electrode 210 may be disposed at a higher level than an upper surface of the first-1 portion 210aa. In other words, a distance D4 between the upper surface of the substrate 100 and the upper surface of the second portion 210b of the first electrode 210 may be greater than a distance D3 between the upper surface of the substrate 100 and the upper surface of the first-1 portion 210aa of the first electrode 210.

The first electrode 210 may be a reflective electrode. The first electrode 210 may include a reflective film including silver (Ag), magnesium (Mg), aluminum (Al), platinum (Pt), palladium (Pd), gold (Au), nickel (Ni), neodymium (Nd), iridium (Ir), chrome (Cr), and a compound thereof. In an embodiment, the first electrode 210 may further include a transparent or translucent conductive layer formed on at least one of upper and lower portions of the reflective film. The transparent or translucent electrode layer may include at least one of indium tin oxide (ITO), indium zinc oxide (IZO), indium oxide (In₂O₃), indium gallium oxide (IGO), and aluminum zinc oxide (AZO). For example, the first electrode 210 may have a stacked structure of ITO/Ag/ITO.

The light scattering layer 215 may be disposed in the first area R1. The light scattering layer 215 may overlap the groove 207G of the via insulating layer 207 in a plan view. The light scattering layer 215 may not overlap the second area R2. In an embodiment, the light scattering layer 215 may be disposed in the groove 207G of the via insulating layer 207. For example, the light scattering layer 215 may be disposed to fill the groove 207G of the via insulating layer 207. FIG. 6 illustrates that the light scattering layer 215 has a substantially flat upper surface. However, the disclosure is not limited thereto. For example, the upper surface of the light scattering layer 215 may have a convex shape at the center.

The light scattering layer 215 may include an organic material 215a and a scattering body 215b dispersed in the organic material 215a. The organic material 215a of the light scattering layer 215 may be, for example, photosensitive polyimide (PSPI) or the like. The scattering body 215b included in the light scattering layer 215 may be metal oxide particles. For example, the scattering body 215b may include metal oxide particles such as titanium oxide (TiO₂), ZnO, or tin oxide (SnO₂). A size and concentration of the scattering body 215b may vary depending on the embodiments.

The light scattering layer 215 may scatter light by the scattering body 215b dispersed in the organic material 215a, thereby improving light efficiency toward the front. For example, the light scattering layer 215 may recycle light by surface plasmon resonance and/or recycle light by a waveguide, thereby improving light efficiency toward the front.

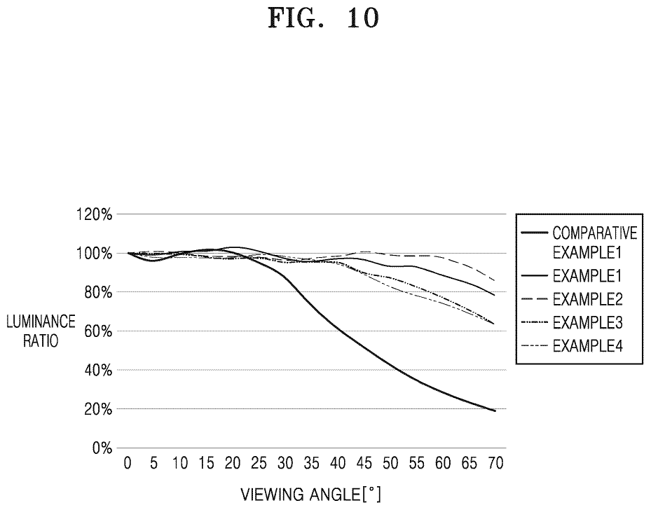

A thickness TH of the light scattering layer 215 may be in a range of about 1.5 μm to about 4 μm. In case that the thickness TH of the light scattering layer 215 is less than about 1.5 μm, a luminance deviation depending on the viewing angle may increase, as described with reference to FIGS. 10 to 12. In case that the thickness TH of the light scattering layer 215 is less than 1.5 μm, a color deviation depending on the viewing angle may increase. In case that the thickness TH of the light scattering layer 215 exceeds 4 μm, a pixel shrinkage problem may occur due to outgasing.

In the first area R1, in case that the characteristics depending on the viewing angle are improved by including the inclination portion 210ab of the first electrode 210, light efficiency toward the front may decrease in case that the light scattering layer 215 is not included. In embodiments, the light scattering layer 215 may be formed on the first portion 210a of the first electrode 210 in the first area R1, thereby improving the characteristics depending on the viewing angle and improving the light efficiency toward the front.

In the second area R2 in which the light scattering layer 215 is not disposed, light may be reflected by the first electrode 210, causing a resonance effect of light, and in the first area R1, the first light-emitting diode LED1 may include the light scattering layer 215 between the first electrode 210 and the first intermediate layer 220 so that a resonance effect of light may not occur. Accordingly, the first area R1 may be referred to as a non-resonant area, and the second area R2 may be referred to as a resonant area. In the second area R2 of the light-emitting diode LED, the resonance effect of light may occur, and thus, the light efficiency toward the front may increase.

In case that the light scattering layer 215 is disposed throughout the light-emitting diode LED and the resonance effect of light does not occur, front light efficiency may decrease. In an embodiment, the first area R1, which is the non-resonant area, and the second area R2, which is the resonant area, may be simultaneously included to improve the luminance deviation and/or color deviation depending on the viewing angle and improve the light efficiency toward the front.

Depending on the embodiment, an area of the first area R1 and an area of the second area R2 may be variously modified. In the embodiment, as shown in FIGS. 4 and 6, the area of the first area R1 may be less than the area of the second area R2 in a plan view. In other words, an area of a region in which a light-emitting area overlaps the groove 207G of the via insulating layer 207 may be less than an area of a region in which the light-emitting area does not overlap the groove 207G of the via insulating layer 207. An area of the first portion 210a of the first electrode 210 may be less than an area of the second portion 210b of the first electrode 210 exposed by the pixel opening 209OP defined in the pixel-defining layer 209. For example, the area of the first area R1 may be in a range of about 20% to about 50% of the first light-emitting area EA1.

A light-transmitting conductive layer 218 may be disposed in each pixel. The light-transmitting conductive layer 218 may be disposed in an area corresponding to each first electrode 210. The light-transmitting conductive layers 218 respectively corresponding to neighboring pixels may be disposed to be spaced apart from each other.

The light-transmitting conductive layer 218 may be disposed in the first area R1 and the second area R2. The light-transmitting conductive layer 218 may overlap the groove 207G of the via insulating layer 207 and may overlap an area disposed outside the groove 207G in a plan view. The light-transmitting conductive layer 218 may be disposed on the light scattering layer 215. The light-transmitting conductive layer 218 may be disposed on the light scattering layer 215 in the first area R1 and on the first electrode 210 in the second area R2. For example, the light-transmitting conductive layer 218 may contact the light scattering layer 215 in the first area R1 and contact the first electrode 210 in the second area R2. Part of the light-transmitting conductive layer 218 may be disposed between the light scattering layer 215 and the intermediate layer 220 in the first area R1, and the remaining part of the light-transmitting conductive layer 218 may be disposed between the second portion 210b of the first electrode 210 and the intermediate layer 220, in the second area R2. In other words, the light-transmitting conductive layer 218 may be disposed between the light scattering layer 215 and the first emission layer 222 in the first area R1, and may be disposed between the second portion 210b of the first electrode 210 and the first emission layer 222 in the second area R2.

The light-transmitting conductive layer 218 may include an inorganic material. For example, the light-transmitting conductive layer 218 may include an inorganic material such as a metal or a metal oxide. For example, the light-transmitting conductive layer 218 may be transparent or translucent. For example, the light-transmitting conductive layer 218 may include at least one of ITO, IZO, ZnO, In₂O₃, IGO, and AZO.

Although it is shown that the light-transmitting conductive layer 218 includes a single layer, the disclosure is not limited thereto. For example, the light-transmitting conductive layer 218 may include two or more layers including an inorganic material. For example, the light-transmitting conductive layer 218 may include a first inorganic layer and a second inorganic layer on the first inorganic layer. For example, each of the first inorganic layer and the second inorganic layer may include at least one of ITO, IZO, ZnO, In₂O₃, IGO, and AZO. For example, the light-transmitting conductive layer 218 may include a first inorganic layer including ITO and a second inorganic layer including IZO.

The pixel-defining layer 209 may be disposed on the light-transmitting conductive layer 218. The pixel-defining layer 209 may have the pixel opening 209OP exposing a central portion of each light-transmitting conductive layer 218. The pixel-defining layer 209 may cover an edge of the light-transmitting conductive layer 218. The pixel opening 209OP defined in the pixel-defining layer 209 may overlap the groove 207G of the via insulating layer 207 in a plan view. A width of the pixel opening 209OP defined in the pixel-defining layer 209 may be greater than a width of the groove 207G of the via insulating layer 207.

The pixel-defining layer 209 may include an organic insulating material. In another embodiment, the pixel-defining layer 209 may include an inorganic insulating material such as silicon nitride (SiNₓ) or silicon oxide (SiO₂). In some embodiments, the pixel-defining layer 209 may include an organic insulating material and an inorganic insulating material.

The pixel-defining layer 209 may include a light-blocking material. For example, the light-blocking material of the pixel-defining layer 209 may be black. The light-blocking material may include carbon black, carbon nanotubes, resin or paste containing black dye, metal particles such as Ni, Al, Mo, and an alloy thereof, metal oxide particles, or metal nitride particles. In case that the pixel-defining layer 209 includes a light-blocking material, reflection of external light by metal structures disposed under the pixel-defining layer 209 may be reduced. However, the disclosure is not limited thereto. In another embodiment, the pixel-defining layer 209 may not include a light-blocking material but may include a light-transmitting organic insulating material.

The spacer 211 may be disposed on the pixel-defining layer 209. The spacer 211 may include an organic insulating material such as polyimide. In another embodiment, the spacer 211 may include an inorganic insulating material, such as silicon nitride (SiNₓ) or silicon oxide (SiO₂), or may include an organic insulating material and an inorganic insulating material.

In an embodiment, the spacer 211 and the pixel-defining layer 209 may include a same material. The pixel-defining layer 209 and the spacer 211 may be formed together in a mask process using a halftone mask or the like. In another embodiment, the spacer 211 and the pixel-defining layer 209 may include different materials.

The intermediate layer 220 may be disposed on the first electrode 210. The intermediate layer 220 may be disposed on the light scattering layer 215 and the light-transmitting conductive layer 218. The intermediate layer 220 may be disposed on the pixel-defining layer 209. At least a part of the intermediate layer 220 may be disposed in the pixel opening 209OP defined in the pixel-defining layer 209. The intermediate layer 220 may include the first common layer 221, an emission layer 222 (i.e., the first emission layer 222), and the second common layer 223.

The emission layer 222 may be disposed in the pixel opening 209OP defined in the pixel-defining layer 209. The emission layer 222 may include an organic material including fluorescent or phosphorescent material that may emit blue, green, or red light. The organic material described above may be a low-molecular weight organic material or a polymer organic material. In another embodiment, the emission layer 222 may include an inorganic material including quantum dots. The quantum dots may be crystals of semiconductor compounds, and may include a material that may emit light of various emission wavelengths depending on the size of the crystal. The quantum dots may include, for example, a group III-VI semiconductor compound, a group II-VI semiconductor compound, a group III-V semiconductor compound, a group III-VI semiconductor compound, a group I-III-VI semiconductor compound, a group IV-VI semiconductor compound, a group IV elements or compound, or a combination thereof.

The first common layer 221 and the second common layer 223 may be disposed under and over the emission layer 222, respectively. For example, the first common layer 221 may include a hole transport layer (HTL), or may include an HTL and a hole injection layer (HIL). For example, the second common layer 223 may include an electron transport layer (ETL), or may include an ETL and an electron injection layer (EIL). In an embodiment, the second common layer 223 may not be provided.

While the emission layer 222 is disposed in each pixel to correspond to the pixel opening 209OP defined in the pixel-defining layer 209, each of the first common layer 221 and the second common layer 223 may be formed to cover an entire area of the substrate 100. In other words, each of the first common layer 221 and the second common layer 223 may be formed to entirely cover the display area DA of the substrate 100.

The second electrode 230 may include a conductive material with a low work function. For example, the second electrode 230 may include a (semi-)transparent layer including Ag, Mg, Al, Pt, Pd, Au, NI, Nd, Ir, Cr, lithium (Li), calcium (Ca), ytterbium (Yb), or an alloy thereof. For example, the second electrode 230 may include a magnesium silver (AgMg) or silver ytterbium (AgYb). In an embodiment, the second electrode 230 may further include a layer including ITO, IZO, ZnO, or In₂O₃, over the (semi-)transparent layer including the materials described above. Layers from the first electrode 210 to the second electrode 230 may form a light-emitting diode LED.

The encapsulation layer 300 may be disposed on the first to third light-emitting diodes LED1, LED2, and LED3. The encapsulation layer 300 may include at least one inorganic film layer and at least one organic film layer. For example, the encapsulation layer 300 may include a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include an inorganic insulating material such as SiO₂, SiNₓ, silicon oxynitride (SiON), Al₂O₃, TiO₂, tantalum oxide (Ta₂O₅), hafnium oxide (HfO₂), or ZnO. The first inorganic encapsulation layer 310 and the second inorganic encapsulation layer 330 may each have a single-layered or multi-layered structure including the inorganic insulating materials described above.

The organic encapsulation layer 320 may relieve internal stress of the first inorganic encapsulation layer 310 and/or the second inorganic encapsulation layer 330. The organic encapsulation layer 320 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, acryl-based resin (e.g., poly(methyl methacrylate), polyacrylic acid, or the like), or a combination thereof.

The organic encapsulation layer 320 may have flowability and may be formed by applying a material including monomers and reacting the monomers to combine to form a polymer by using heat or light such as ultraviolet rays. In another embodiment, the organic encapsulation layer 320 may be formed by applying a polymer material.

The touch sensing layer 400 may be disposed on the encapsulation layer 300. The touch sensing layer 400 may include a first conductive layer MTL1, a first touch insulating layer 410, a second conductive layer MTL2, and a second touch insulating layer 420. The first conductive layer MTL1 may be disposed on (e.g., directly disposed on) the encapsulation layer 300, and the first conductive layer MTL1 may be disposed on (e.g., directly disposed on) the second inorganic encapsulation layer 330 of the encapsulation layer 300. However, the disclosure is not limited thereto.

In an embodiment, the touch sensing layer 400 may include an insulating film (not shown) between the first conductive layer MTL1 and the encapsulation layer 300. The insulating film may be disposed on the second inorganic encapsulation layer 330 of the encapsulation layer 300 to planarize a surface on which the first conductive layer MTL1 or the like is disposed, and the first conductive layer MTL1 may be disposed on (e.g., directly disposed on) the insulating film. The insulating film may include an inorganic insulating material such as SiO₂, SiNₓ, or SiON. In another embodiment, the insulating film may include an organic insulating material.

In an embodiment, the first touch insulating layer 410 may be disposed on the first conductive layer MTL1. The first touch insulating layer 410 may include an inorganic material or an organic material. In case that the first touch insulating layer 410 includes an inorganic material, the first touch insulating layer 410 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In case that the first touch insulating layer 410 includes an organic material, the first touch insulating layer 410 may include at least one of an acryl-based resin, a methacryl-based resin, polyisoprene, a vinyl-based resin, an epoxy-based resin, an urethane-based resin, a cellulose-based resin, and a perylene-based resin.

In an embodiment, the second conductive layer MTL2 may be disposed on the first touch insulating layer 410. The second conductive layer MTL2 may serve as a sensor for detecting a user's touch input. The first conductive layer MTL1 may serve as a connection part for connecting the second conductive layer MTL2, which is patterned, in a direction. In an embodiment, both the first conductive layer MTL1 and the second conductive layer MTL2 may serve as sensors, and the first conductive layer MTL1 and the second conductive layer MTL2 may be electrically connected through a contact hole CH. As described above, because both the first conductive layer MTL1 and the second conductive layer MTL2 serve as sensors, a resistance of a touch electrode may be reduced, and thus the user's touch input may be quickly detected.

In an embodiment, the first conductive layer MTL1 and the second conductive layer MTL2 may have, for example, a mesh structure, so that light emitted from the first to third light-emitting diodes LED1, LED2, and LED3 may pass through the first conductive layer MTL1 and the second conductive layer MTL2. In an embodiment, the first conductive layer MTL1 and the second conductive layer MTL2 may be disposed not to overlap each of the first to third light-emitting areas EA1, EA2, and EA3 of the first to third light-emitting diodes LED1, LED2, and LED3.

The first conductive layer MTL1 and the second conductive layer MTL2 may include a metal layer and a transparent conductive layer. The metal layer may include at least one of Mo, Ag, Ti, Cu, Al, and an alloy thereof. The transparent conductive layer may include a transparent conductive oxide such as ITO, IZO, ZnO, or indium tin zinc oxide (ITZO). In an embodiment, the transparent conductive layer may include a conductive polymer such as poly(3,4-ethylenedioxythiophene) (PEDOT), metal nanowires, carbon nanotubes, or graphene.

In an embodiment, the second touch insulating layer 420 may be disposed on the second conductive layer MTL2. The second touch insulating layer 420 may include an inorganic material or an organic material. In case that the second touch insulating layer 420 includes an inorganic material, the second touch insulating layer 420 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In case that the second touch insulating layer 420 includes an organic material, the second touch insulating layer 420 may include at least one of an acryl-based resin, a methacryl-based resin, polyisoprene, a vinyl-based resin, an epoxy-based resin, an urethane-based resin, a cellulose-based resin, and a perylene-based resin.

In another embodiment, the touch sensing layer 400 may include the first conductive layer MTL1, the first touch insulating layer 410, and the second conductive layer MTL2, but may not include the second touch insulating layer 420. The light-shielding layer 510 may have a structure covering the second conductive layer MTL2, and a part of the first touch insulating layer 410 may be exposed through an opening 510OP defined in the light-shielding layer 510.

The anti-reflection layer 500 may be disposed on the touch sensing layer 400. The anti-reflection layer 500 may include the light-shielding layer 510 and a color filter layer 521. In an embodiment, the anti-reflection layer 500 may further include the light-shielding layer 510 and an overcoat layer 525 disposed on the color filter layer 521.

The light-shielding layer 510 may include a material capable of blocking light. For example, the light-shielding layer 510 may include an organic material having a high light absorption rate. The light-shielding layer 510 may include a black pigment or a black dye. The light-shielding layer 510 may include a photosensitive organic material and may include, for example, a colorant such as a pigment or a dye.

The light-shielding layer 510 may have an opening 510OP overlapping each of the first to third light-emitting areas EA1, EA2, and EA3 in a plan view. The opening 510OP defined in the light-shielding layer 510 may include a first to third openings 510OP1, 510OP2, and 510OP3 respectively corresponding to the first to third light-emitting diodes LED1, LED2, and LED3. The first to third light-emitting areas EA1, EA2, and EA3 may be defined by the pixel opening 209OP defined in the pixel-defining layer 209. In an embodiment, the opening 510OP defined in the light-shielding layer 510 may overlap the pixel opening 209OP defined in the pixel-defining layer 209, and a width of the opening 510OP defined in the light-shielding layer 510 may be greater than a width of the pixel opening 209OP defined in the pixel-defining layer 209.

A body portion of the light-shielding layer 510 in which the opening 510OP is provided may overlap a body portion of the pixel-defining layer 209 in a plan view. For example, the body portion of the light-shielding layer 510 may overlap only the body portion of the pixel-defining layer 209. The body portion of the light-shielding layer 510 may be a portion distinguished from the opening 510OP defined in the light-shielding layer 510 and may refer to a portion having a certain volume (thickness). Likewise, the body portion of the pixel-defining layer 209 may be a portion distinguished from the pixel opening 209OP defined in the pixel-defining layer 209 and may refer to a portion having a certain volume.

The color filter layer 521 may include color filters 521a, 521b, and 521c of different colors respectively corresponding to the first to third light-emitting diodes LED1, LED2, and LED3.

In an embodiment, the first to third color filters 521a, 521b, and 521c may be respectively disposed in the first to third openings 510OP1, 510OP2, and 510OP3 defined in the light-shielding layer 510. In an embodiment, the first to third color filters 521a, 521b, and 521c may have colors corresponding to light emitted from the first to third light-emitting diodes LED1, LED2, and LED3, respectively. In an embodiment, in case that the first light-emitting diode LED1 emits red light, the first color filter 521a may be a red color filter, in case that the second light-emitting diode LED2 emits green light, the second color filter 521b may be a green color filter, and in case that the third light-emitting diode LED3 emits blue light, the third color filter 521c may be a blue color filter. The light-shielding layer 510 may be disposed between neighboring color filters and may surround edges of each of the pixels P1, P2, and P3 in a plan view.

The overcoat layer 525 may be disposed on the light-shielding layer 510 and the color filter layer 521. The overcoat layer 525 may be a colorless light-transmitting layer that does not have a color in the visible light band, and may planarize an upper surface of the light-shielding layer 510 and an upper surface of the color filter layer 521. The overcoat layer 525 may include a colorless light-transmitting organic material such as an acryl-based resin, and may be covered with a window (not shown). The window may include a transparent (light-transmitting) material. For example, the window may include a glass substrate or a polymer substrate.

In the display device 1 described below, the same reference signs as those of FIGS. 4 to 6 denote the same members, and thus, redundant descriptions thereof are omitted, and only differences are described.

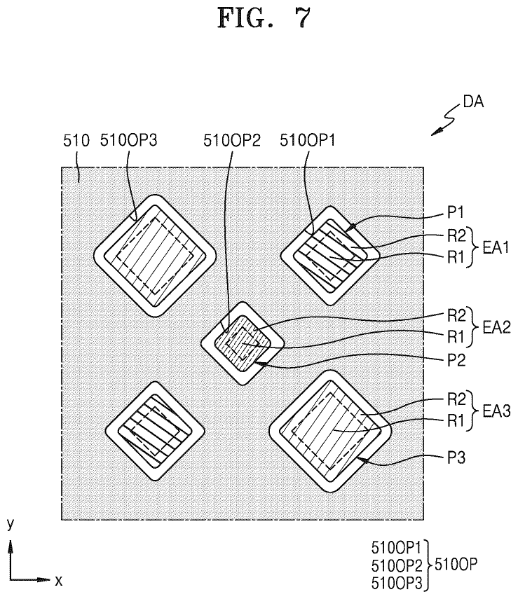

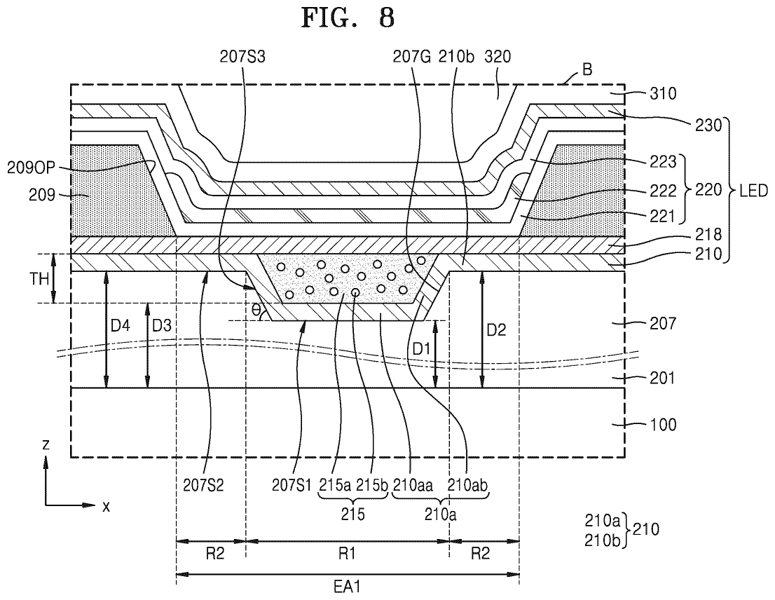

FIG. 7 is a schematic plan view illustrating part of the display area DA of the display device 1 according to another embodiment. FIG. 8 is a schematic enlarged view of region B of FIG. 5 according to another embodiment.

Referring to FIGS. 7 and 8, in a plan view, the area of the first area R1 may be greater than the area of the second area R2 in a plan view. In other words, an area of a region in which a light-emitting area overlaps the groove 207G of the via insulating layer 207 may be greater than an area of a region in which the light-emitting area does not overlap the groove 207G of the via insulating layer 207. An area of the first portion 210a of the first electrode 210 may be greater than an area of the second portion 210b of the first electrode 210 exposed by the pixel opening 209OP defined in the pixel-defining layer 209.

For example, the area of the first area R1 may be greater than about 50% to about 80% of the first light-emitting area EA1. In products that require an improvement in luminance deviation and color deviation depending on viewing angle, the area of the first area R1 may be formed to be greater than the area of the second area R2.

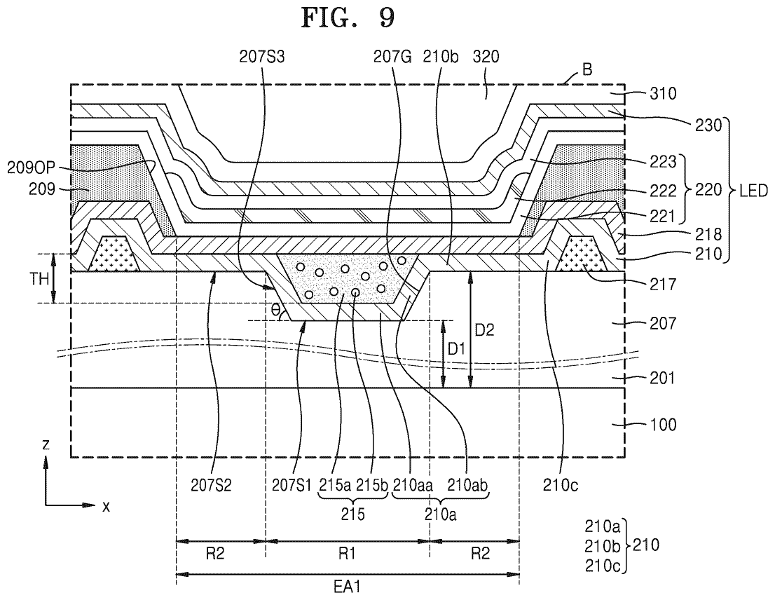

FIG. 9 is a schematic enlarged view of region B of FIG. 5 according to another embodiment.

Referring to FIG. 9, the display device 1 may further include an insulating pattern 217 on the via insulating layer 207. The insulating pattern 217 may overlap the pixel-defining layer 209 in a plan view.

The first electrode 210 may include the first portion 210a overlapping the groove 207G of the via insulating layer 207 in the first area R1, the second portion 210b disposed outside the groove 207G of the via insulating layer 207 in the second area R2, and a third portion 210c extending from the second portion 210b and having at least a portion disposed on a side surface of the insulating pattern 217. In an embodiment, the third portion 210c of the first electrode 210 may be disposed on side and upper surfaces of the insulating pattern 217.

The first portion 210a of the first electrode 210 may include the first-1 portion 210aa disposed on the first surface 207S1 and the first-2 portion 210ab disposed on the third surface 207S3. The first-1 portion 210aa of the first electrode 210 may be a flat portion having a substantially flat upper surface, and the first-2 portion 210ab may be referred to as a first inclination portion inclined from the first-1 portion 210aa. A portion of the third portion 210c of the first electrode 210 disposed on the side surface of the insulating pattern 217 may be referred to as a second inclination portion. In an embodiment, the first electrode 210 may further include the second inclination portion, thereby improving light efficiency by using light recycling by a waveguide.

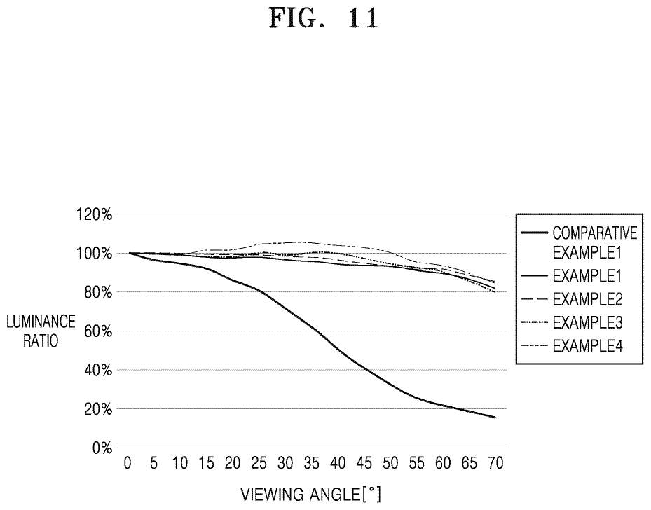

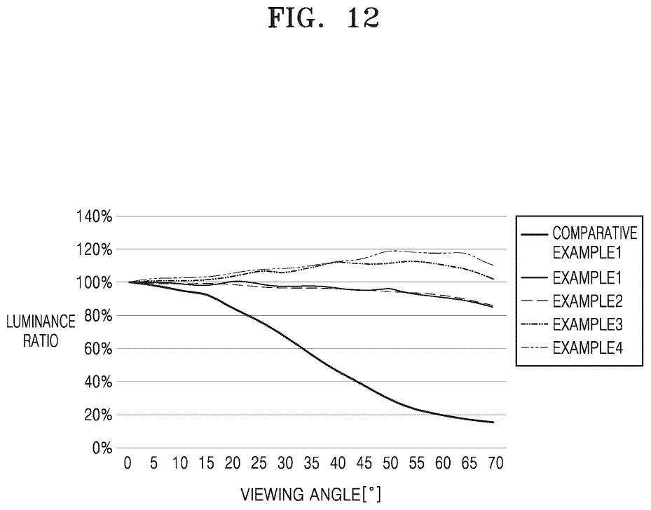

FIG. 10 is a schematic graph showing luminance ratios depending on viewing angles in a COMPARATIVE EXAMPLE and Examples in which a pixel emitting red light is included. FIG. 11 is a schematic graph showing luminance ratios depending on viewing angles in a COMPARATIVE EXAMPLE and EXAMPLES in which a pixel emitting green light is included. FIG. 12 is a schematic graph showing luminance ratios depending on viewing angles in a COMPARATIVE EXAMPLE and EXAMPLES in which a pixel emitting blue light is included. In the COMPARATIVE EXAMPLE of FIGS. 10 to 12, a light-emitting diode of a pixel may not include a light scattering layer, in EXAMPLES 1 and 2, the light-emitting diode of the pixel may include a light scattering layer having a thickness of about 1.5 μm, and in EXAMPLES 3 and 4, the light-emitting diode of the pixel may include a light scattering layer having a thickness of about 1 μm.

Referring to FIGS. 10 to 12, it can be seen that the luminance deviation depending on the viewing angle is improved in EXAMPLES 1 to 4 compared to COMPARATIVE EXAMPLE1 in which a light scattering layer is not included. As shown in FIG. 10, in case that the thickness of the light scattering layer is about 1 μm as in EXAMPLES 3 and 4 in a pixel emitting red light, it can be seen that a luminance ratio at a high viewing angle is greatly reduced. As shown in FIG. 11, in case that the thickness of the light scattering layer is about 1 μm as in EXAMPLES 3 and 4 in a pixel emitting green light, it can be seen that a luminance ratio at a high viewing angle is relatively reduced. As shown in FIG. 12, in case that the thickness of the light scattering layer is about 1 μm as in EXAMPLES 3 and 4 in a pixel emitting blue light, it can be seen that a luminance ratio at a high viewing angle increases. On the other hand, in each of FIGS. 10 to 12, in case that the thickness of the light scattering layer is about 1.5 μm as shown in EXAMPLES 1 and 2, it can be seen that the luminance deviation at low viewing angles and high viewing angles is not large. Thus, in case that the thickness of the light scattering layer is formed to be about 1.5 μm or more, the luminance deviation may be greatly improved.

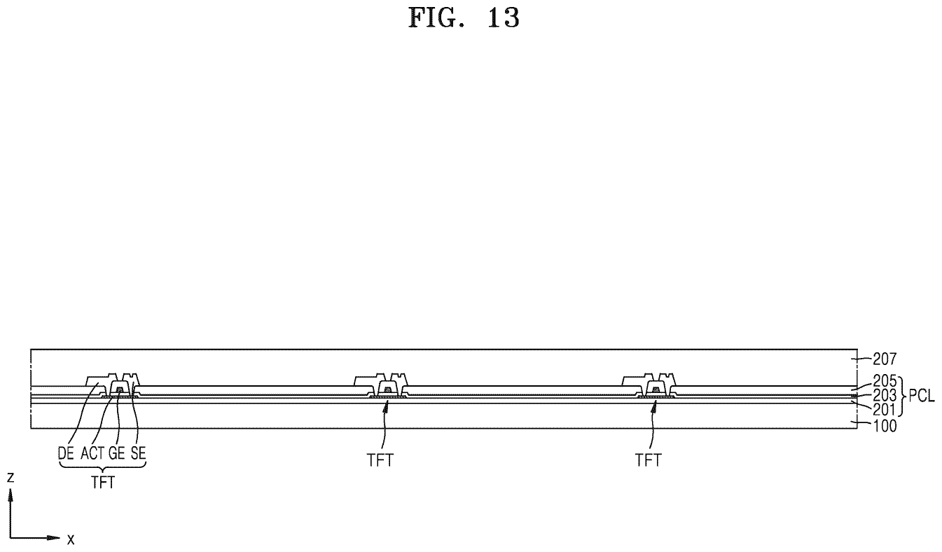

FIGS. 13 to 19 are schematic cross-sectional views illustrating a method of manufacturing a display device, according to an embodiment.

FIG. 13 schematically illustrates a method of manufacturing a display device in an area corresponding to FIG. 5. FIGS. 14 to 19 schematically illustrate a method of manufacturing a display device in an area corresponding to region B of FIG. 5.

Referring to FIG. 13, the substrate 100 may be formed, and the pixel circuit layer PCL including the thin-film transistor TFT and an insulating layer may be formed on the substrate 100. The via insulating layer 207 may be formed on the pixel circuit layer PCL.

In an embodiment, the buffer layer 201 on the substrate 100, the semiconductor layer ACT on the buffer layer 201, the gate insulating layer 203 on the semiconductor layer ACT, a gate electrode GE on the gate insulating layer 203, the interlayer insulating layer 205 on the gate electrode GE, and the source electrode SE and the drain electrode DE on the interlayer insulating layer 205 may be sequentially formed.

The via insulating layer 207 may be formed on the thin-film transistor TFT. The via insulating layer 207 may be formed on the interlayer insulating layer 205 to cover the thin-film transistor TFT. The via insulating layer 207 may be formed to cover the source electrode SE and the drain electrode DE.

In an embodiment, the via insulating layer 207 may be formed by applying an organic material such as a general-purpose polymer, such as PSPI, polyimide, PS, PC, BCB, HMDSO, and PMMA, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer. In an embodiment, in order to provide a flat upper surface of the via insulating layer 207, chemical and mechanical polishing may be performed on the upper surface of the via insulating layer 207 after applying the organic material.

Referring to FIG. 14, the groove 207G may be formed by removing a part of the via insulating layer 207. In an embodiment, in case that the via insulating layer 207 includes a photosensitive material, a part of the via insulating layer 207 may be removed by a photolithography process. In another embodiment, a part of the via insulating layer 207 may be removed by an etching process.

By removing a part of the via insulating layer 207, the upper surface of the via insulating layer 207 may be formed to include the first surface 207S1 positioned at a relatively low level, the second surface 207S2 positioned at a higher level than the first surface 207S1, and the third surface 207S3 connecting the first surface 207S1 and the second surface 207S2 to each other. The groove 207G of the via insulating layer 207 may be defined by the first surface 207S1 and the third surface 207S3 of the via insulating layer 207. Accordingly, the distance D2 between the upper surface of the substrate 100 and the second surface 207S2 of the via insulating layer 207 may be greater than a distance D1 between the upper surface of the substrate 100 and the first surface 207S1 of the via insulating layer 207.

In an embodiment, an inclination angle of surfaces forming the groove 207G of the via insulating layer 207 may be formed in a range of about 20° to about 40°. For example, the angle θ between the first surface 207S1 and the third surface 207S3 of the via insulating layer 207 may be formed in a range of about 20° to about 40°.

Referring to FIGS. 5 and 14, a part of the via insulating layer 207 may be removed to form a contact hole, which passes through the via insulating layer 207 and connects the thin-film transistor TFT to the first electrode 210. The forming of the contact hole in the via insulating layer 207 may be formed simultaneously or may be formed sequentially with the forming of the groove 207G on the via insulating layer 207. For example, a through hole may be formed in the via insulating layer 207 after the groove 207G is formed on the via insulating layer 207, or the groove 207G may be formed on the via insulating layer 207 after the through hole is formed in the via insulating layer 207.

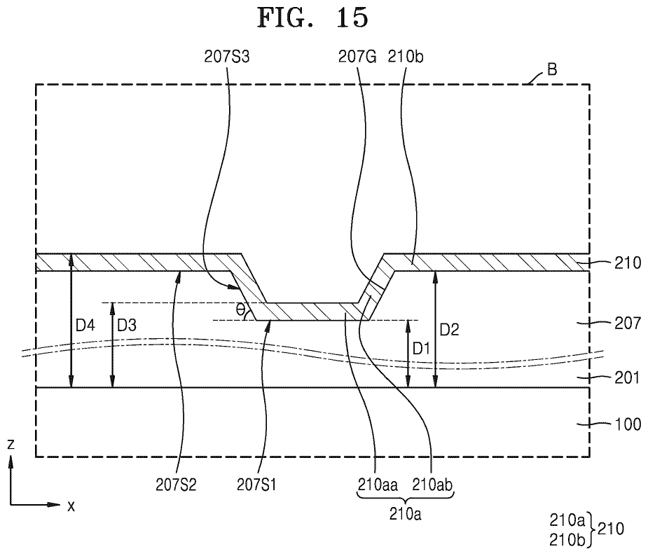

Referring to FIG. 15, the first electrode 210 may be formed on the via insulating layer 207. Referring to FIGS. 5 and 15, the first electrode 210 may be formed in each pixel. In other words, the first electrodes 210 respectively corresponding to neighboring pixels may be formed to be spaced apart from each other. For example, the first electrodes 210 may be formed by depositing a conductive material and removing a part of the conductive material by an etching process.

The first electrode 210 may include the first portion 210a disposed in the groove 207G of the via insulating layer 207 and the second portion 210b disposed outside the groove 207G of the via insulating layer 207. The first portion 210a of the first electrode 210 may be disposed on the first surface 207S1 and the third surface 207S3 of the via insulating layer 207. The second portion 210b of the first electrode 210 may be disposed on the second surface 207S2 of the via insulating layer 207. The first portion 210a of the first electrode 210 may include the first-1 portion 210aa disposed on the first surface 207S1 and the first-2 portion 210ab disposed on the third surface 207S3. The first-1 portion 210aa of the first electrode 210 may be a flat portion having a substantially flat upper surface, and the first-2 portion 210ab may be an inclination portion inclined from the first-1 portion 210aa.

The first electrode 210 may be formed to have a step structure. For example, the upper surface of the second portion 210b of the first electrode 210 may be disposed at a higher level than an upper surface of the first portion 210a of the first electrode 210. For example, the upper surface of the second portion 210b of the first electrode 210 may be disposed at a higher level than the upper surface of the first-1 portion 210aa. In other words, the distance D4 between the upper surface of the substrate 100 and the upper surface of the second portion 210b of the first electrode 210 may be greater than the distance D3 between the upper surface of the substrate 100 and the upper surface of the first-1 portion 210aa of the first electrode 210.

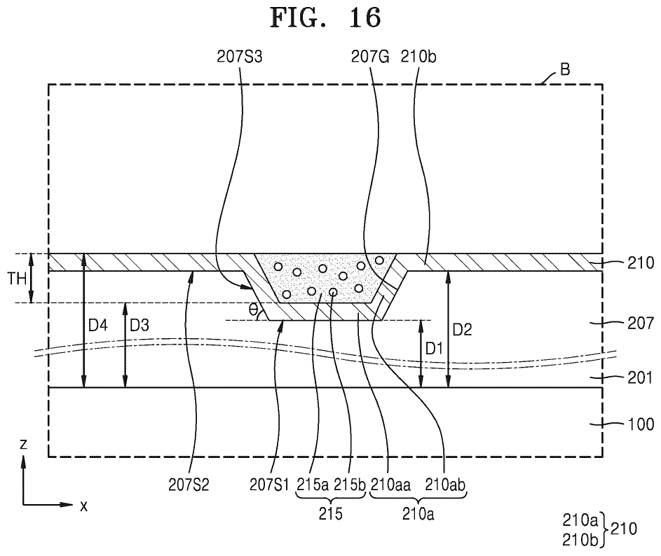

Referring to FIG. 16, the light scattering layer 215 may be formed on the first portion 210a of the first electrode 210. The light scattering layer 215 may be formed to fill the groove 207G of the via insulating layer 207. In other words, the light scattering layer 215 may be disposed in the groove 207G of the via insulating layer 207. Accordingly, the light scattering layer 215 may be disposed to overlap the groove 207G of the via insulating layer 207 in a plan view and may not be disposed outside the groove 207G of the via insulating layer 207. The light scattering layer 215 may be formed to have a substantially flat upper surface. For example, the upper surface of the light scattering layer 215 and the upper surface of the second portion 210b of the first electrode 210 may be formed to be positioned at substantially a same level. In an embodiment, the upper surface of the light scattering layer 215 may be formed to have a convex upper surface in the groove 207G.

The light scattering layer 215 may include an organic material 215a and a scattering body 215b dispersed in the organic material 215a. The organic material 215a of the light scattering layer 215 may include a photosensitive organic material, such as PSPI. The scattering body 215b included in the light scattering layer 215 may be metal oxide particles. For example, the scattering body 215b may include metal oxide particles such as TiO₂, ZnO, or SnO₂. The size and concentration of the scattering body 215b may vary depending on embodiments.

In an embodiment, the light scattering layer 215 may be formed by applying the organic material 215a containing the scattering body 215b throughout the display area DA and removing a part of the applied organic material 215a, so as to be disposed only in the groove 207G of the via insulating layer 207 and not to be disposed outside the groove 207G of the via insulating layer 207. For example, a part of the light scattering layer 215 may be removed by a photolithography process.

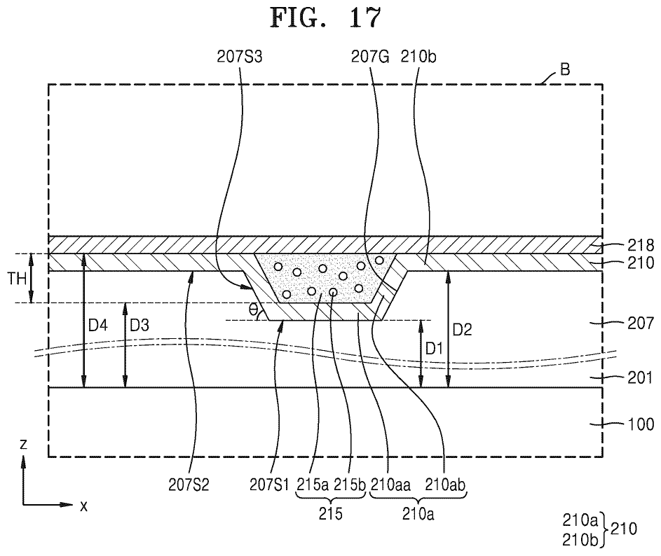

Referring to FIG. 17, the light-transmitting conductive layer 218 may be formed on the light scattering layer 215 and the first electrode 210. Referring to FIGS. 5 and 17, the light-transmitting conductive layer 218 may be formed in each pixel. In other words, the light-transmitting conductive layers 218 respectively corresponding to neighboring pixels may be formed to be spaced apart from each other. For example, the light-transmitting conductive layer 218 may be formed by depositing a conductive material and removing a part of the conductive material by an etching process.

The light-transmitting conductive layer 218 may be formed to overlap the groove 207G of the via insulating layer 207 in a plan view and not overlap an area outside the groove 207G in a plan view. A part of the light-transmitting conductive layer 218 may contact the light scattering layer 215, and a remaining part may be formed to contact the first electrode 210.

The light-transmitting conductive layer 218 may include an inorganic material. For example, the light-transmitting conductive layer 218 may include an inorganic material such as a metal or a metal oxide. For example, the light-transmitting conductive layer 218 may be transparent or translucent. For example, the light-transmitting conductive layer 218 may include at least one of ITO, IZO, ZnO, In₂O₃, IGO, and AZO.

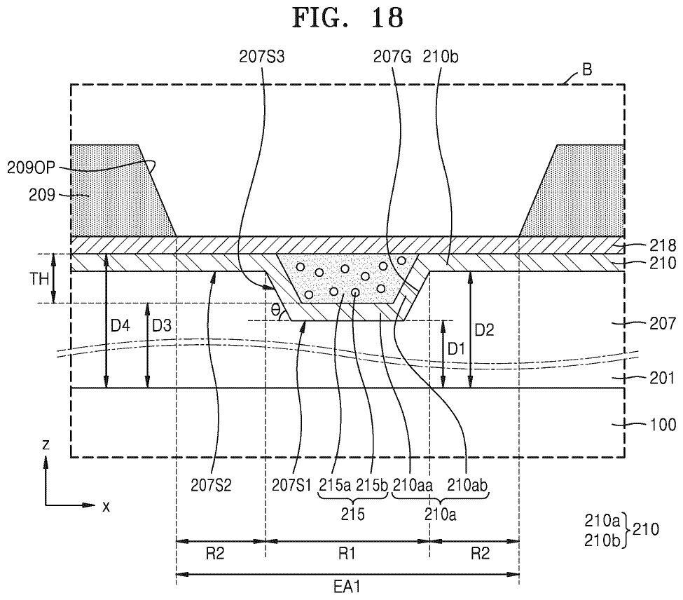

Referring to FIG. 18, the pixel-defining layer 209 may be formed on the light-transmitting conductive layer 218. After the pixel-defining layer 209 is formed, the pixel opening 209OP may be formed by removing a part of the pixel-defining layer 209, so that a central portion of each light-transmitting conductive layer 218 is exposed. The pixel opening 209OP defined in the pixel-defining layer 209 may overlap the groove 207G of the via insulating layer 207 in a plan view. The width of the pixel opening 209OP defined in the pixel-defining layer 209 may be greater than the width of the groove 207G of the via insulating layer 207. The pixel-defining layer 209 may cover an edge of the light-transmitting conductive layer 218.

The pixel-defining layer 209 may include an organic insulating material. In another embodiment, the pixel-defining layer 209 may include an inorganic insulating material such as SiNₓ or SiO₂. In some embodiments, the pixel-defining layer 209 may include an organic insulating material and an inorganic insulating material.

The pixel-defining layer 209 may include a light-blocking material. For example, the light-blocking material of the pixel-defining layer 209 may be black. The light-blocking material may include carbon black, carbon nanotubes, resin or paste containing black dye, metal particles such as Ni, Al, Mo, and an alloy thereof, metal oxide particles, or metal nitride particles. In case that the pixel-defining layer 209 includes a light-blocking material, reflection of external light by metal structures disposed under the pixel-defining layer 209 may be reduced. However, the disclosure is not limited thereto. In another embodiment, the pixel-defining layer 209 may not include the light-blocking material but may include a light-transmitting organic insulating material.

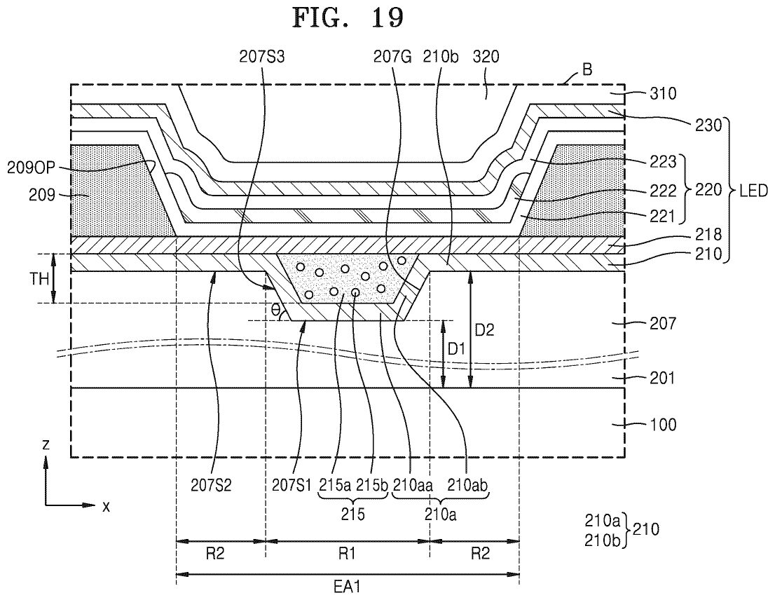

Referring to FIG. 19, the light-emitting diode LED may be formed by sequentially forming the intermediate layer 220 and the second electrode 230 on the light-transmitting conductive layer 218. The intermediate layer 220 may include the first common layer 221, the emission layer 222, and the second common layer 223. Each of the first common layer 221, the second common layer 223, and the second electrode 230 may be integrally formed to cover an entire area of the substrate 100. In other words, the first common layer 221, the second common layer 223, and the second electrode 230 may be formed to be shared by each pixel.

Referring to FIG. 5 again, the encapsulation layer 300 sealing the light-emitting diode LED may be formed, the touch sensing layer 400 may be formed on the encapsulation layer 300, and the anti-reflection layer 500 may be formed on the touch sensing layer 400.

The display device according to the embodiment may be applied to various electronic devices. An electronic device according to an embodiment of the present disclosure may include the display device (e.g., the display device of FIG. 1) described above, and may further include modules or apparatuses having additional functions in addition to the display device.

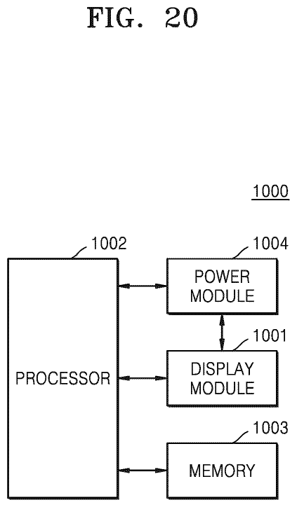

FIG. 20 is a block diagram of an electronic device according to an embodiment.

Referring to FIG. 20, an electronic device 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic device 1000.

At least one of the components of the electronic device 1000 described above may be included in the display device according to the embodiments described above. In addition, a part among the individual modules functionally included in one module may be included in the display device, and another part may be provided separately from the display device. For example, the display device may include the display module 1001, while the processor 1002, the memory 1003, and the power module 1004 may be provided in the form of other devices within the electronic device 1000 except for the display device.

In an embodiment, the display module 1001 included in the display device may drive based on the image data signal and the input control signal received from the processor 1002.

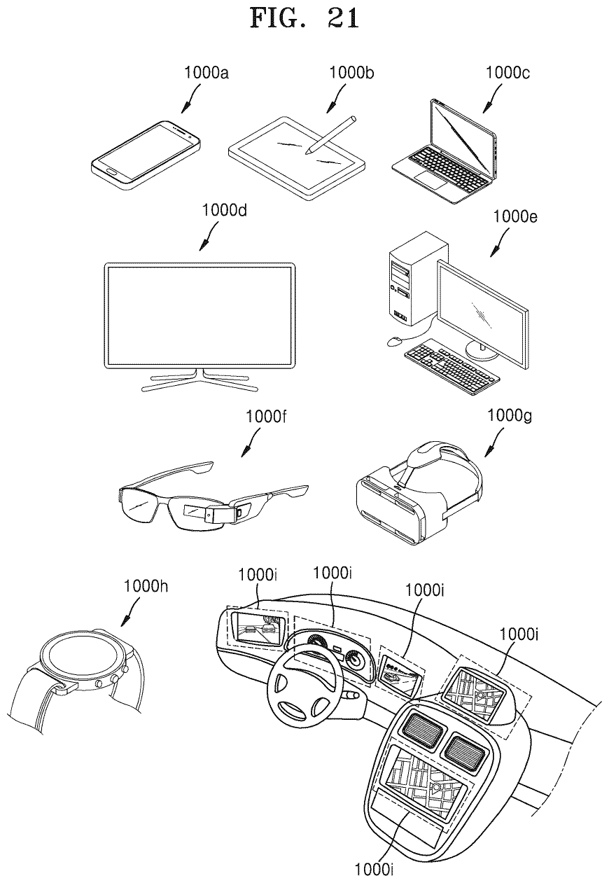

FIG. 21 is schematic diagrams of electronic devices according to various embodiments.

Referring to FIG. 21, various electronic devices to which display devices according to embodiments are applied may include not only image display electronic devices such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

In a light-emitting diode or a display device including the light-emitting diode, according to an embodiment, luminance deviation and/or color deviation depending on the viewing angle may be improved, and light efficiency may be improved. However, these effects are only examples, and the scope of the disclosure is not limited thereby.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel circuit layer disposed on a substrate and comprising a thin-film transistor;
a via insulating layer disposed on the pixel circuit layer and including a groove; and
a light-emitting diode disposed on the via insulating layer and comprising a first area overlapping the groove and a second area surrounding the first area in a plan view, wherein
the light-emitting diode comprises:
a first electrode comprising a first portion disposed in the groove in the first area and a second portion extending from the first portion and disposed in the second area;
a light scattering layer disposed on the first portion of the first electrode and comprising a scattering body;
a light-transmitting conductive layer disposed on the light scattering layer;
an emission layer disposed on the light-transmitting conductive layer; and
a second electrode on the emission layer, and
a distance between the substrate and the first portion of the first electrode is less than a distance between the substrate and the second portion of the first electrode.

2. The display device of claim 1, wherein
an upper surface of the via insulating layer comprises a first surface, a second surface at a higher level than the first surface, and a third surface connecting the first surface to the second surface, and
the first surface of the via insulating layer and the third surface of the via insulating layer define the groove.

3. The display device of claim 2, wherein
the first portion of the first electrode is disposed on the first surface of the via insulating layer and the third surface of the via insulating layer, and
the second portion of the first electrode is disposed on the second surface of the via insulating layer.

4. The display device of claim 2, wherein an angle between the first surface of the via insulating layer and the third surface of the via insulating layer is in a range of about 20° to about 40°.

5. The display device of claim 1, wherein the light scattering layer is disposed in the groove of the via insulating layer.

6. The display device of claim 1, wherein the light-transmitting conductive layer contacts the light scattering layer in the first area and contacts the first electrode in the second area.

7. The display device of claim 1, wherein the light-transmitting conductive layer comprises a first inorganic layer and a second inorganic layer on the first inorganic layer.

8. The display device of claim 1, further comprising:
a pixel-defining layer on the light-transmitting conductive layer, the pixel-defining layer including a pixel opening that exposes a part of the light-transmitting conductive layer.

9. The display device of claim 8, wherein, in a plan view, an area of the first area is about 20% to about 80% of an area of a light-emitting area of the light-emitting diode defined by the pixel-defining layer.

10. The display device of claim 9, wherein, in a plan view, the area of the first area is less than an area of the second area.

11. The display device of claim 9, wherein, in a plan view, the area of the first area is greater than an area of the second area.

12. The display device of claim 8, further comprising:
an insulating pattern overlapping the pixel-defining layer in a plan view and disposed between the via insulating layer and the first electrode,
wherein the first electrode further comprises a third portion extending from the second portion and disposed on a side surface of the insulating pattern.

13. The display device of claim 1, wherein a thickness of the light scattering layer is in a range of about 1.5 μm to about 4 μm.

14. The display device of claim 1, further comprising:
an encapsulation layer disposed on the light-emitting diode and encapsulating the light-emitting diode; and
a color filter layer disposed on the encapsulation layer.

15. A display device comprising:
a pixel circuit layer disposed on a substrate and comprising a thin-film transistor;
a via insulating layer disposed on the pixel circuit layer and including a groove;
a first electrode comprising a first portion disposed in the groove of the via insulating layer and a second portion extending from the first portion and disposed outside the groove;
a light scattering layer disposed on the first portion of the first electrode and comprising a scattering body;
an emission layer disposed on the light scattering layer;
a second electrode on the emission layer; and
a light-transmitting conductive portion comprising a portion disposed between the light scattering layer and the emission layer and another portion disposed between the second portion of the first electrode and the emission layer.

16. The display device of claim 15, wherein
an upper surface of the via insulating layer comprises a first surface, a second surface at a higher level than the first surface, and a third surface connecting the first surface to the second surface, and
the first surface of the via insulating layer and the third surface of the via insulating layer define the groove.

17. The display device of claim 16, wherein
the first portion of the first electrode is disposed on the first surface of the via insulating layer and the third surface of the via insulating layer, and
the second portion of the first electrode is disposed on the second surface of the via insulating layer.

18. The display device of claim 16, wherein an angle between the first surface of the via insulating layer and the third surface of the via insulating layer is in a range of about 20° to about 40°.

19. The display device of claim 15, further comprising:
a pixel-defining layer disposed on the first electrode and including a pixel opening that exposes a part of the first electrode.

20. The display device of claim 19, further comprising:
an insulating pattern overlapping the pixel-defining layer in a plan view and disposed between the via insulating layer and the first electrode,
wherein the first electrode further comprises a third portion extending from the second portion and disposed on a side surface of the insulating pattern.

21. The display device of claim 15, wherein a thickness of the light scattering layer is in a range of about 1.5 μm to about 4 μm.

22. The display device of claim 15, further comprising:
an encapsulation layer disposed on the second electrode; and
a color filter layer disposed on the encapsulation layer.

23. A light-emitting diode comprising:
a first electrode comprising a first portion and a second portion, the first portion comprising a flat portion and an inclination portion and the second portion surrounding the first portion in a plan view and connected to the flat portion of the first portion by the inclination portion of the first portion;
a light scattering layer disposed on the first portion of the first electrode and comprising a scattering body;
a light-transmitting conductive layer disposed on the light scattering layer;
an emission layer disposed on the light-transmitting conductive layer; and
a second electrode disposed on the emission layer.

24. The light-emitting diode of claim 23, wherein
an upper surface of the second portion is at a higher level than an upper surface of the flat portion of the first portion, and
the inclination portion of the first portion is disposed between the flat portion and the second portion and inclined from the flat portion of the first portion.

25. The light-emitting diode of claim 23, wherein
the light-transmitting conductive layer is in contact with the second portion of the first electrode, and
the light scattering layer is disposed between the first portion of the first electrode and the light-transmitting conductive layer.

26. The light-emitting diode of claim 23, wherein a thickness of the light scattering layer is in a range of about 1.5 μm to about 4 μm.

27. An electronic device comprising a display device, wherein
the display device comprises:
a pixel circuit layer disposed on a substrate and comprising a thin-film transistor;
a via insulating layer disposed on the pixel circuit layer and including a groove; and
a light-emitting diode disposed on the via insulating layer and comprising a first area overlapping the groove and a second area surrounding the first area in a plan view,
the light-emitting diode comprises:
a first electrode comprising a first portion disposed in the groove in the first area and a second portion extending from the first portion and disposed in the second area;
a light scattering layer disposed on the first portion of the first electrode and comprising a scattering body;
a light-transmitting conductive layer disposed on the light scattering layer;
an emission layer disposed on the light-transmitting conductive layer; and
a second electrode on the emission layer, and
a distance between the substrate and the first portion of the first electrode is less than a distance between the substrate and the second portion of the first electrode.

28. The electronic device of claim 27, further comprising:
a display module;
a processor; a power module; and
a memory,
wherein the display device includes one of the display module, the processor, the power module, and the memory.
